(19) United States
(12) Patent Application Publication
(10) Pub. No.: US 2024/0401922 A1
(43) Pub. Date: Dec. 5, 2024

(54) SYSTEM AND METHOD/PROCESS FOR COMMERCIAL BLASTING

(71) Applicant: Orica International Pte Ltd, Singapore (SG)

(72) Inventors: Anh Tuan NGUYEN, Singapore (SG); Steven KOTSONIS, Singapore (SG); Gil Edward SMITH, Singapore (SG)

(21) Appl. No.: 18/698,863

(22) PCT Filed: Oct. 6, 2022
(86) PCT No.: PCT/SG2022/050714

§ 371 Date: Apr. 5, 2024

(30) Foreign Application Priority Data
Oct. 7, 2021 (SG) 10202111176X

(51) Int. Cl. F42D 1/05; H03J 3/20

(52) U.S. Cl. CPC F42D 1/05; H03J 3/20

(57) ABSTRACT

A system including a range extension system for extending a range of magnetic induction (MI) signals along a pathway for commercial/civil blasting operations that use a wireless blasting-related device, the range extension system including an elongated element configured to extend the range of the MI signals along the pathway.

### RELATED APPLICATIONS

The present application is related to Singaporean Patent Application No. 10202111176X, entitled “System and method/process for commercial blasting”, lodged on 7 Oct. 2021, the originally filed specification of which is hereby incorporated herein by reference.

### TECHNICAL FIELD

Aspects of the present disclosure relate to systems and methods/processes for assisting commercial blasting based on blasting-related devices that are deployable or deployed within portions of physical media (e.g., a rock formation) intended to be blasted as part of a commercial blasting operation. Such blasting-related devices include initiation devices (e.g., detonators) positioned in boreholes or blastholes (also written, “bore hole” or “blast hole”).

### BACKGROUND

In commercial/civil blasting operations, boreholes are narrow shafts that may be bored into rock vertically downwards (into a floor), vertically upwards (into a roof), horizontally (into a wall), or at an angle between vertical and horizontal depending on the blast pattern required. For blasting, blast explosives are filled into the boreholes, along with suitable initiating systems, including detonators, and the explosive train is then triggered in a planned sequence based on a blast plan.

For precision mining and excavation, requiring highly accurate timing and superior control, electronic detonators can be used, connected to a blasting machine by electrical communication wires or cables; however, at least for some blasting methods, the wired connections can overlap with sensitive locations, that may result in a discontinuity of the explosives train and/or be undesirably complicated to connect and check, and/or rewire.

Wireless electronic detonators, e.g., triggered by electro/magnetic signals, may be used to avoid complicated wired connections. Wireless initiation systems that communicate by way of magnetic induction (MI) signals, e.g., including WebGen™ wireless initiation devices produced by Orica International Pte Ltd., have recently been developed and used in commercial blasting operations such as underground mining, open cut mining, quarrying and civil blasting applications. Such wireless initiation devices can greatly improve blasting safety, and have given rise to new blasting techniques not previously feasible with conventional lead- or wire-based initiation devices. WebGen™ wireless initiation devices may be configured for reliable unidirectional or 1-way MI based communication over significant, long, or very long distances, e.g., greater than 100 meters, or several to many hundreds of meters (e.g., 100-900 meters), or possibly distances approaching or on the order of a kilometre. Wireless initiation devices may also be configured for bidirectional or 2-way MI based communication.

However, wireless signals can be undesirably attenuated and/or deflected by some rock types, that may exhibit, e.g. high magnetic-susceptibility or conductivity, e.g., magnetite, rendering traditional through-the-earth wireless electronic detonator system unreliable. For example, wireless signal transmission through some rock types may be less than 1 meter (m), and along boreholes in some rock types can be less than 10 m. Furthermore, background noise and/or interference in some rock types, or structures, may be more substantial in a borehole than in an adjacent tunnel/stope, further limiting use of wireless electronic detonators in some rock types/mines.

Some wireless electronic detonators may include wired connections to radio transceivers at the borehole collars, and these may be referred to as “wireless-to-the-collar systems”. Disadvantages of such systems, which use wire to transmit signals from the collar to an electronic detonator/initiating-system in the borehole, may include: (a) the wire is prone to breakage, (b) the sensitive antenna at the collar/surface needs to be physically connected to the in-hole detonator/initiating-system and it is sensitive to breakage creating discontinuity, and/or needs complex/water-proof connections to the down-hole device; and/or (c) the need for sensitive electronics at the collar, which are prone to damage through their location, at or below, the hole collar, which can be disturbed by surface activities, including blasting of nearby holes.

It is desired to address or ameliorate one or more disadvantages or limitations associated with the prior art, or to at least provide a useful alternative.

### SUMMARY

Described herein is a wireless electronic blasting system (WEBS) for assisting blasting, the system including at least one wireless blasting-related device (or “wireless device”) that is deployable or deployed proximate to or within a portion of physical media intended to be blasted as part of a commercial blasting operation, wherein the wireless blasting-related device includes a device-based magnetic induction (MI) signal receiver configured for through the earth (TTE) MI communication.

Described herein is a system, including a range extension system for extending a range of (input) magnetic induction (MI) signals (from intervening media, e.g., air or earth, etc.) along a pathway for commercial/civil blasting operations that use a wireless blasting-related device, the range extension system including an elongated element configured to extend the range of the MI signals along the pathway (to the wireless blasting-related device, configured to generate MI signals (based on the input MI signals) that emanate beyond a physical end of the range extension system).

The elongated element may have a longitudinal length that is significantly greater than its average cross-sectional diameter, optionally having a longitudinal length of more than 1 m, 4 m, 10 m or 75 m, and less than 1 km, 750 m, 50 m or 10 m.

The elongated element may include at least one electrical conductor configured to carry electrical signals that represent the MI signals along the elongated element in or on the electrical conductor (wherein the electrical signals are generated by the input MI signals, and in turn generate the generated MI signals that emanate beyond the physical end).

The extension system may include:
a. a first element configured to be coupled to a first end of the elongated element, wherein the first element is configured to be placed (thus positioned/arranged/configured/oriented) towards a first end of the pathway, wherein the first element is configured to receive the (input) MI signals at a start of the pathway (to generate the electrical signals); and/or
b. a second element configured to be coupled to a second end of the elongated element, wherein the second end is opposite the first end, wherein the second element is configured to be placed at a second end of the pathway, wherein the second element is configured to receive the electrical signals from the elongated element, convert the electrical signals to generated MI signals, and transmit the generated MI signals to the wireless blasting-related device (the physical end of the range extension system may be defined by an end of the second element that is opposite the elongated element, e.g., facing away from the elongated element and towards the wireless blasting-related device).

The electrical conductor may include an electrical cable configured to extend from the first element to the second element, and configured to conduct the electrical signals.

The electrical signals may include modulation frequencies (“MI frequencies”) that are in the MI signals, wherein the MI frequencies optionally include at least one MI frequency from 300 Hz to 3000 Hz (which may be referred to as being in the “ultra low frequency” band designated by the International Telecommunication Union (ITU)) and/or from 3 kHz to 30 kHz (in the “very low frequency” designated by the ITU), and/or from 30 kHz to 300 kHz (in the “low frequency” designated by the ITU), which may include at least one frequency below 9,000 Hz, below 30 kHz, or below 300 kHz, and/or which may include at least one frequency between 1 kHz and 10 kHz, between 1 kHz and 2 kHz, between 2 kHz and 3 kHz, between 3 kHz and 4 kHz, between 3 kHz and 5 kHz, substantially 4 kHz, or between 4 kHz and 5 kHz.

The first element may include at least one first-end antenna configured to transduce the MI signals in intervening media (e.g., air, water, earth, solid material or a mixture thereof) from an MI transmitter into the electrical signals in the electrical conductor, and the second element may include at least one second-end antenna configured to transduce the electrical signals from the electrical conductor into the generated MI signals for the wireless blasting-related device.

The system may include a frequency-tuning circuit with a tuning capability, which can include an electronic tuning circuit to control (or tune) a resonant frequency of the extension system to match the modulation frequencies of the MI signals.

The frequency-tuning circuit may include:
a. a first-end tuning element connected in series or in parallel with the first-end antenna; and/or
b. a second-end tuning element connected in series or in parallel with the second-end antenna.

The frequency-tuning circuit may include at least one capacitive element to tune the resonant frequency during use.

For optimal performance in some embodiments, the second element may be configured to fasten mechanically to the wireless blasting-related device by way of an adaptor configured to hold the second element aligned to an MI Receiver of the wireless blasting-related device and/or to keep the second element close to the MI Receiver of the wireless blasting-related device-specifically aligned to and/or close to a receiver magnetometer in/of the MI Receiver. (The physical end of the range extension system may be defined by an end of the adaptor that is opposite the elongated element, e.g., facing away from the elongated element and towards the wireless blasting-related device.)

The first element may include a first-end projection with high magnetic permeability configured to confine and guide the MI signals to the first-end antenna from the air, wherein the first-end projection includes a rigid rod or a flexible rod or flexible rope.

The extension system may include mutual spacing between adjacent ones of a plurality of the first elements, wherein the mutual spacing is substantially the size of the first elements (e.g., antenna diameter) to mitigate interference (e.g., substantially magnetic) between the adjacent ones of the first elements.

The system may include a plurality of the elongated elements configured to extend to mutually different lengths along the pathway.

The system may include a plurality of the first element and/or a plurality of the second element coupled to the elongated element (to share transmission of the MI signals along the elongated element).

The system may include the wireless blasting-related device, which is optionally a wireless initiation device, a wireless MI signal survey device, or a wireless blast monitoring-and-tracking marker, optionally including: at least one wireless blasting-related device configured to send device-sourced MI signals; and an external MI signal receiver configured to receive the device-sourced MI signals.

The first-end antenna may be formed of a first-end portion of the cable arranged around an MI antenna of the MI transmitter; and/or the second-end antenna may be formed of a second-end portion of the cable arranged in a coil with a plurality of turns (around a frame or drum or bobbin).

The elongated element may guide the (input) MI signals into and along the pathway, and the MI signals may travel in and along the elongated element as magnetic signals by modulation of a magnetic field in the elongated element, optionally wherein the elongated element includes a high permeability composite material. (The physical end of the range extension system may be defined by an end of the elongated element that is facing towards the wireless blasting-related device.)

The elongated element may have high electrical conductivity, forming a high conductivity guide including a conductive medium configured to receive a modulated induced current representing the MI signals induced at its first end. (The physical end of the range extension system may be defined by an end of the elongated element that is facing towards the wireless blasting-related device.)

The range extension system may form (be configured to form) a distribution network of the (input) MI signals by the elongated element including a plurality of elongated branches with respective second ends connected to the first end to emit/transmit the generated MI signals (which are based on and derive from the input MI signals) from the second ends.

### BRIEF DESCRIPTION OF THE FIGURES

Some embodiments are hereinafter described, by way of non-limiting example only, with reference to the accompanying drawings, in which:

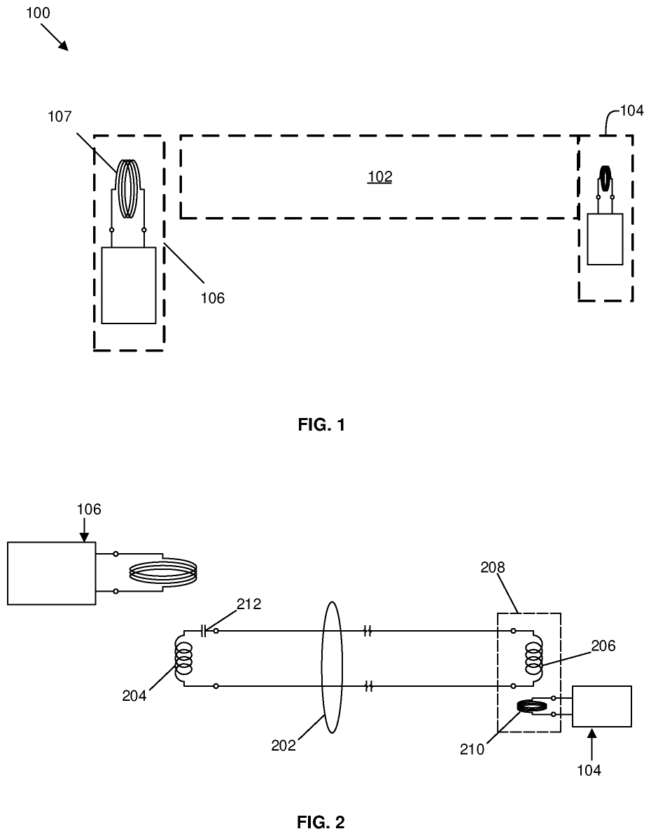

a. FIG. 1 is a schematic diagram of a wireless electronic blasting system (WEBS) with an extension system;

b. FIG. 2 is a diagram of the extension system including a cable and antennae;

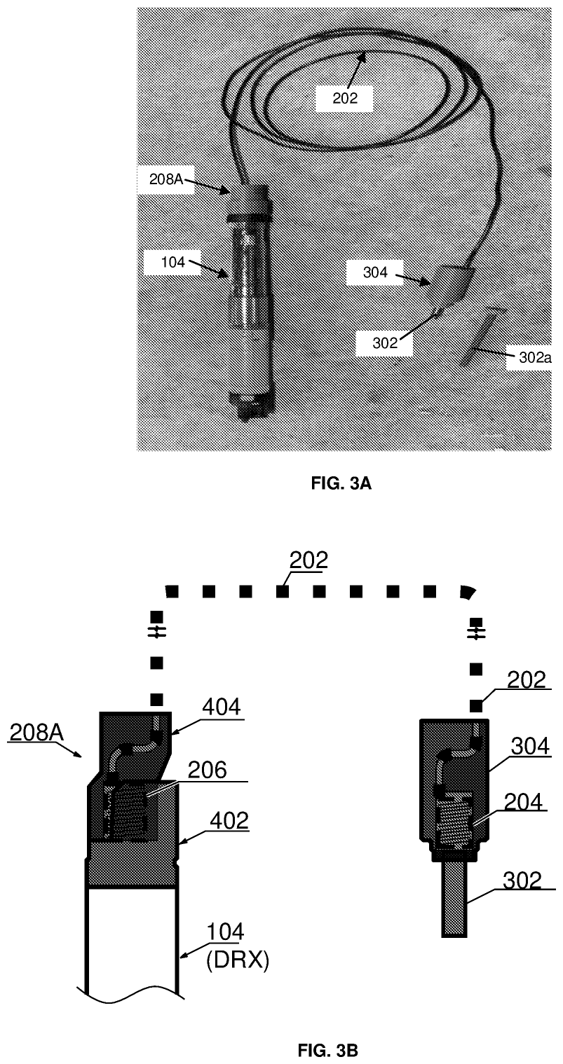

c. FIG. 3A is a photograph of the extension system attached to a wireless blasting-related device with a first adapter;

d. FIG. 3B is a diagram of the extension system including the first adaptor (for a wireless blasting-related device) and a first-end projection (ferrite rod);

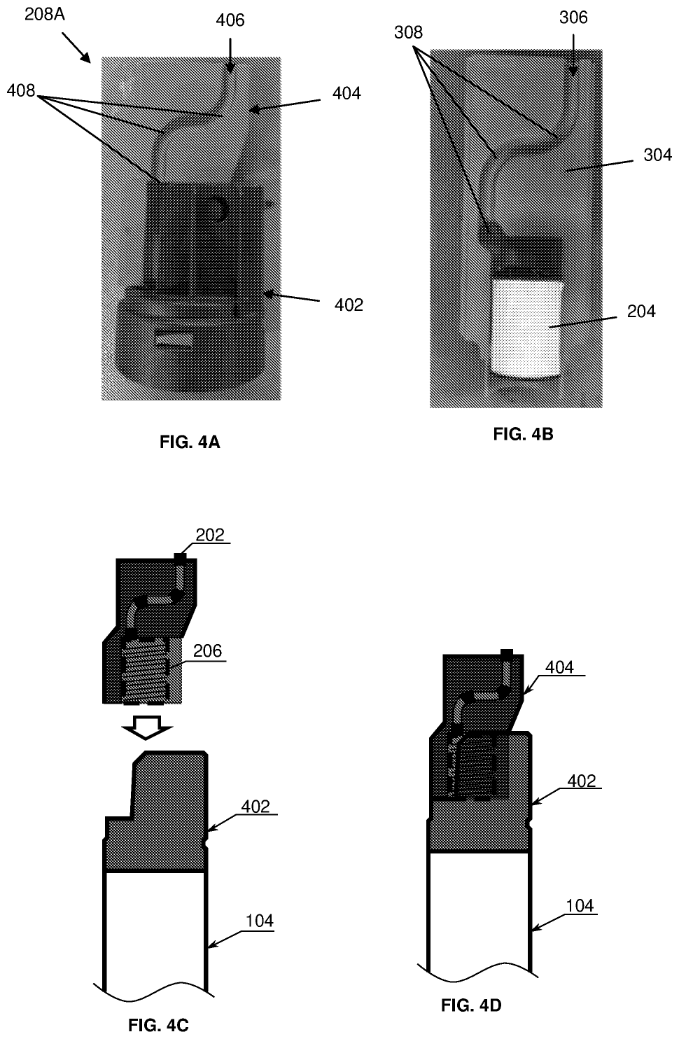

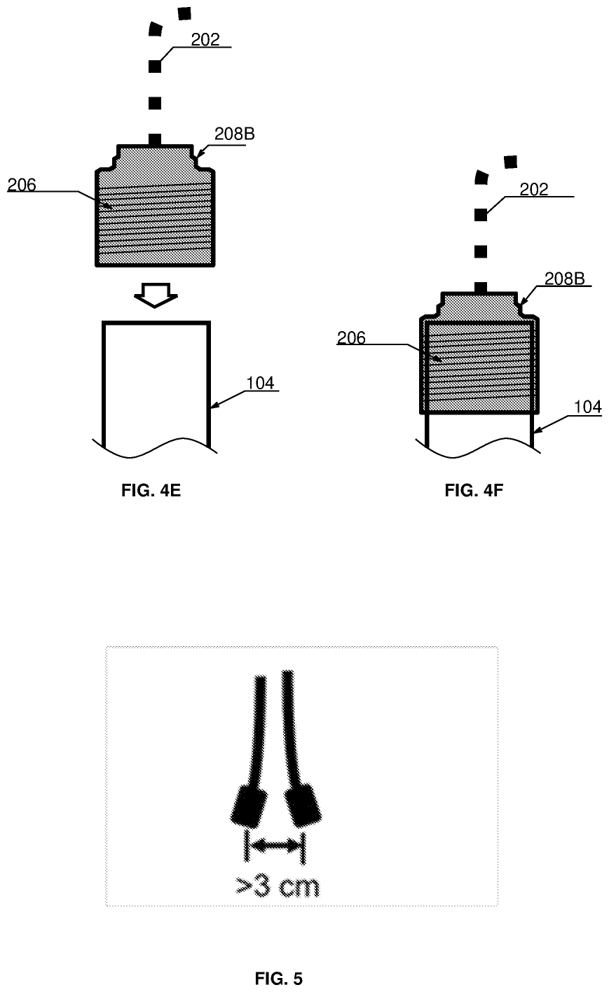

e. FIG. 4A is a photograph of a device lock cap of the first adapter for locking to the wireless blasting-related device, and a central cross-section of a holder attached thereto;

f. FIG. 4B is a photograph of a central cross-section of a holder for holding the cable and one antenna;

g. FIG. 4C is a diagram of the first adaptor with the holder separated from the lock cap;

h. FIG. 4D is a diagram of the first adaptor with the holder coupled to the lock cap;

i. FIG. 4E is a diagram of a second adaptor separated from the wireless blasting-related device;

j. FIG. 4F is a diagram of the second adaptor coupled to the wireless blasting-related device;

k. FIG. 5 is a schematic diagram of a mutual spacing between end elements of the extension system;

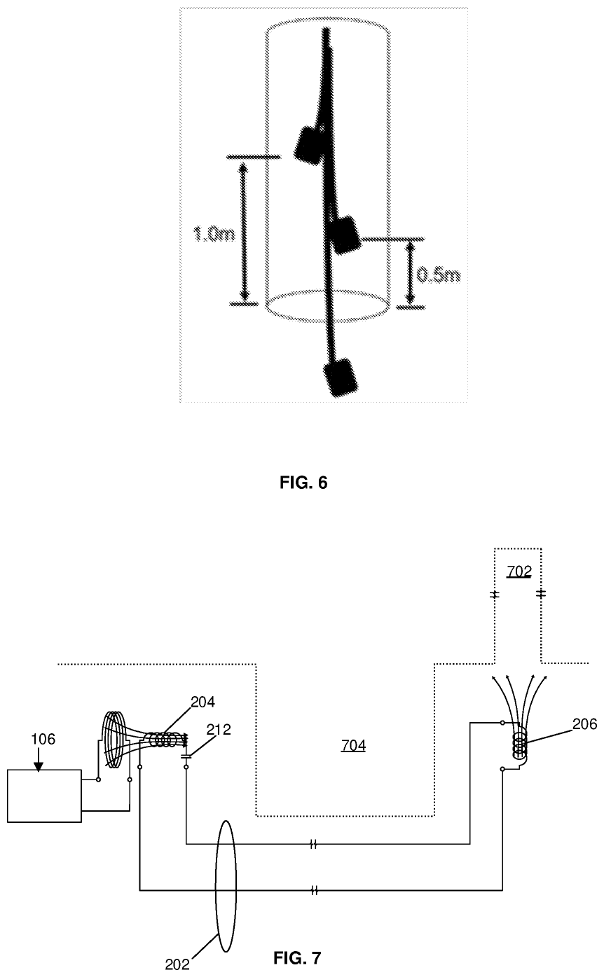

l. FIG. 6 is a schematic diagram of a plurality of possible locations of an end element of the extension system in a borehole;

m. FIG. 7 is a diagram of a “high power” embodiment of the extension system;

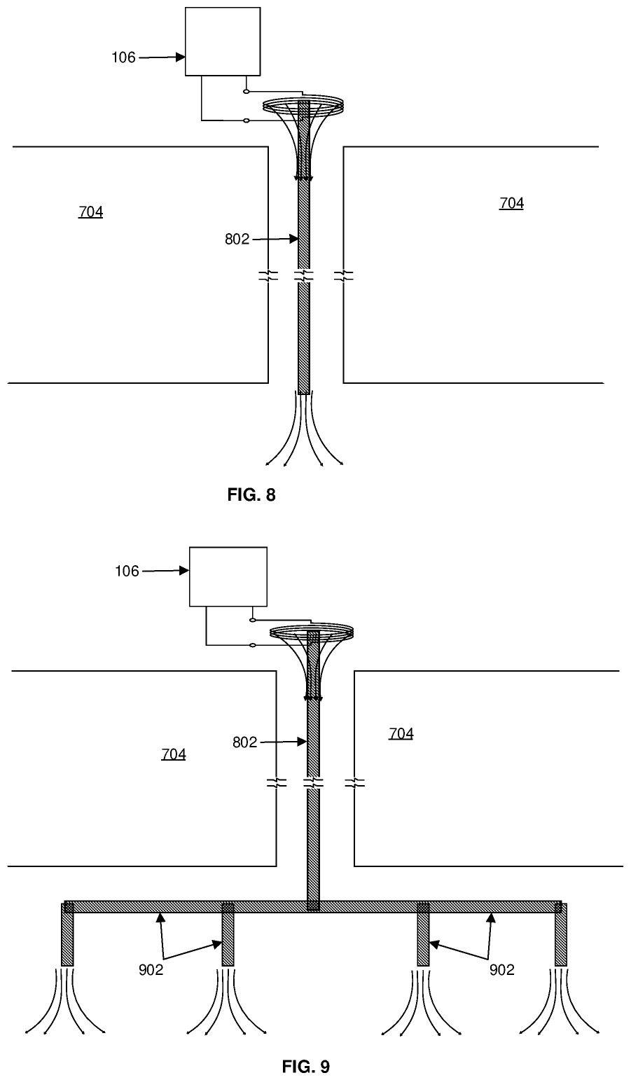

n. FIG. 8 is a diagram of the extension system including a magnetic induction (MI) guide;

o. FIG. 9 is a diagram of the high permeability guide including a plurality of ends;

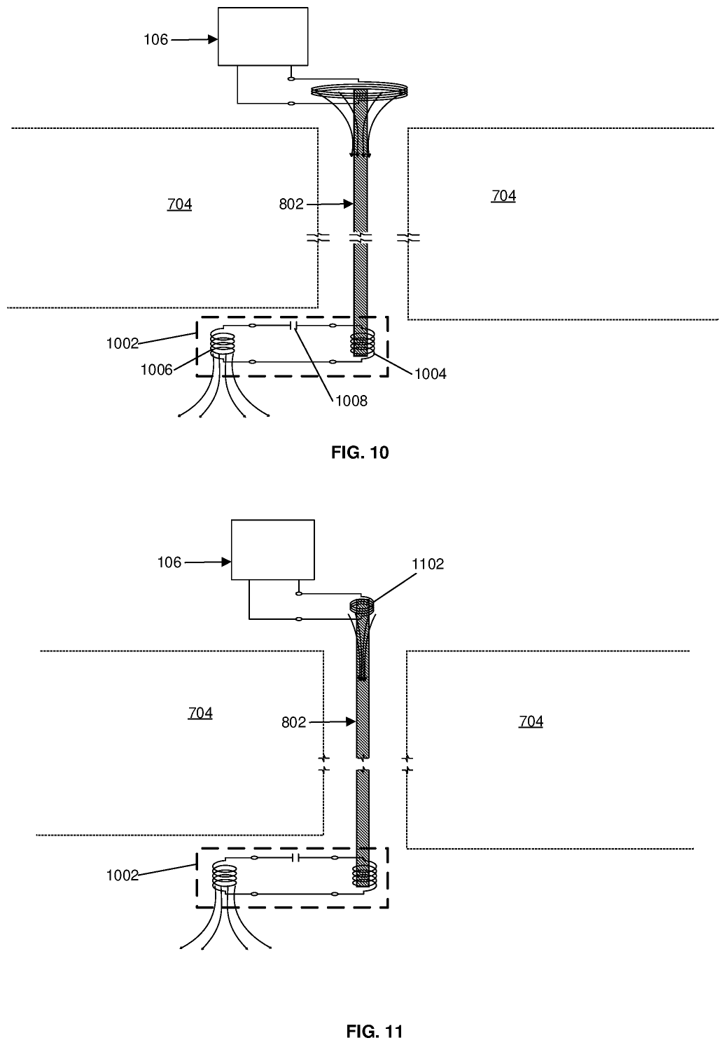

p. FIG. 10 is a diagram of the extension system including a coil pair coupled to the high permeability guide;

q. FIG. 11 is a diagram of a custom antenna of the WEBS coupled to the extension system;

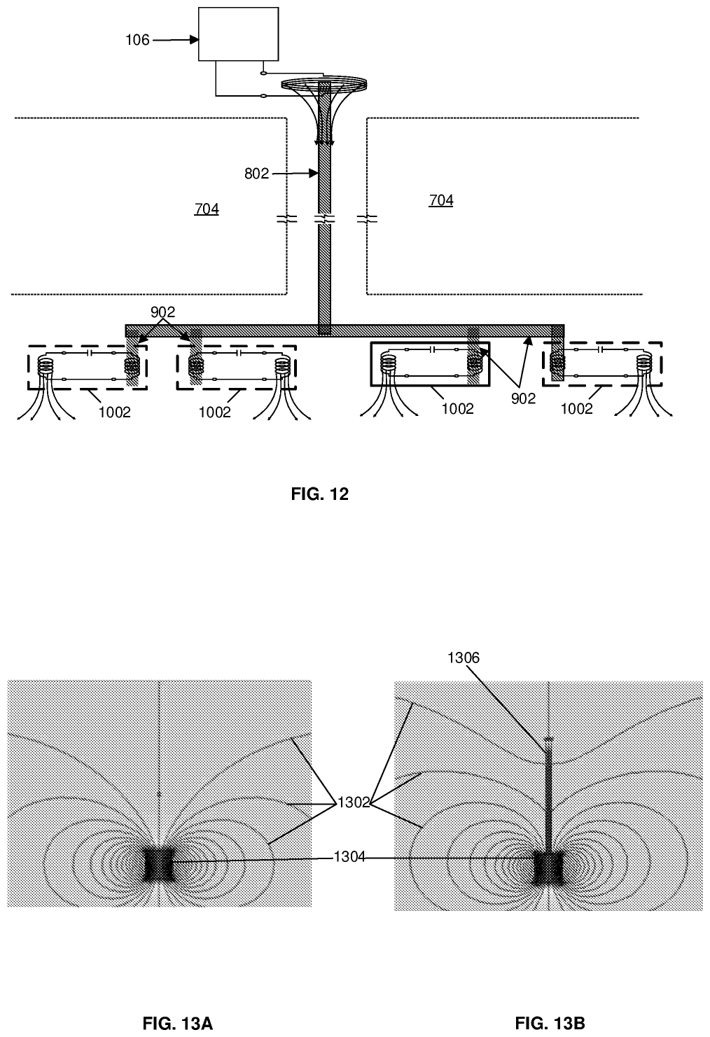

r. FIG. 12 is a diagram of a plurality of the coil pairs coupled to the plurality of ends of the high permeability guide;

s. FIG. 13A is a two-dimensional plot of magnetic field lines emanating from a simulated DRX coil of an example extension system;

t. FIG. 13B is a two-dimensional plot of magnetic field lines emanating from the simulated DRX coil of FIG. 13A including a high permeability guide;

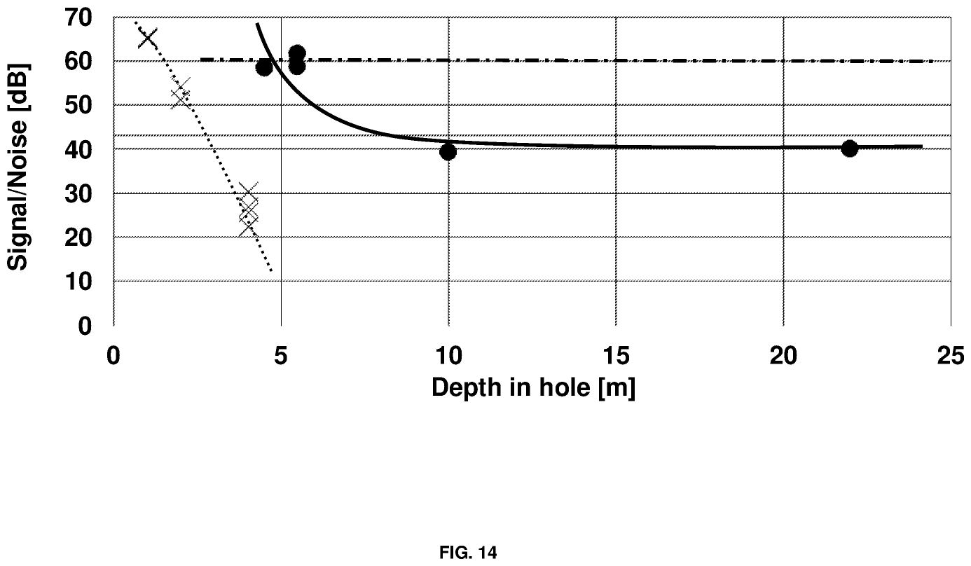

u. FIG. 14 is a graph of experimental results of a measured signal-to-noise ratio as a function of depth in a borehole with (circles) and without (crosses) the extension system; and

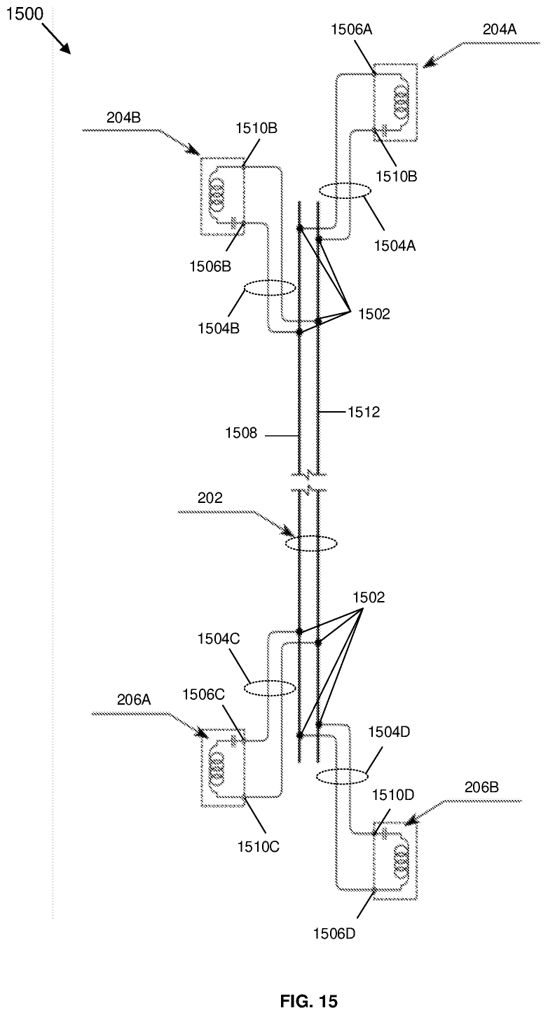

v. FIG. 15 is a diagram of the extension system forming a branching network including the cable and multiple antennae at each end of the cable.

### DETAILED DESCRIPTION

### Extension System

Disclosed herein is a range extension system 102 for extending a range of magnetic induction (MI) signals along a pathway, e.g., across the earth surface, along a hole, a borehole, a passage, or a tunnel in earth, rock, stemming, soil, concrete, brick and/or water, for commercial/civil blasting operations that use at least one wireless blasting-related device 104 (also referred to as a “wireless device 104” herein), which may be a wireless initiation device, e.g., WebGen™ with a disposable receiver (“DRX”), a wireless explosive primer, a wireless MI signal survey device, a device with wireless transmitting/receiving capability, or a wireless blast monitoring-and-tracking marker. The range extension system 102 is configured such that the generated MI signals emanate beyond a physical end of the range extension system 102 to the wireless blasting-related device 104.

As shown in FIG. 1, the extension system 102 may be included in a wireless electronic blasting system (WEBS) 100. The WEBS includes an MI Transmitter 106 with an MI Antenna 107 (e.g., with a plurality of loops/coils) to transmit the MI signals (which become input MI signals into the range extension system 102) into intervening media between the MI Transmitter 106 and the extension system 102, where the intervening media may include the air, earth, rock, stemming, soil, concrete, brick and/or water, for commercial/civil blasting operations. The WEBS 100 includes one or more of the wireless devices 104, e.g., in boreholes, that are configured to receive the MI signals.

The extension system 102 includes an elongated element configured to extend the range of the MI signals along the pathway. The elongated element is configured to extend along the pathway (e.g., substantially into the borehole or substantially along the tunnel).

The elongated element has a longitudinal length that is significantly greater than its average cross-sectional diameter (thus described as “elongated” or “elongate”).

The elongated element may extend in length, for example, in underground mining, from a point on the surface, through the earth, to a location able to express the generated MI signals, so that they can be used to communicate with desired wireless devices 104, or for example in surface mining, or other applications, this elongated element may run across the surface in order to extend the MI signal. The length of these elongated elements may be from 50% to 500% of the theoretical MI signal range of the selected transmission system in the WEBS 100 in the absence of the extension system including the elongated element. For example, if the theoretical transmission range of a transmission antenna in the WEBS 100 is a radius of 150 m, then the elongated element may be up to substantially 75 m to 750 m long. For in-hole applications, the length of the elongated element may be substantially more than 3 m, or more than 25 m, or more than 50 m.

In use, the elongated element enhances/extends the range of MI signal transmission through or over earth/rock that otherwise attenuates said MI signals, or where the distance to the intended receiver is otherwise greater than the range of the corresponding MI signal transmitter. In operation, a first end of the extension system 102 may be placed where the MI signals are strong, for example in the air, water, solid material or a mixture thereof, from the MI Transmitter 106—e.g., near the collar of the borehole. The first end can capture/detect/receive the (input) MI signals outside of the pathway, and the elongated element effectively relays the MI signals along its length to its second end, emitting/emanating the corresponding generated MI signals, and thence to the wireless device 104. In examples, the first end is outside the collar, and/or substantially 0.5 m inside the collar, and/or substantially 1 m inside the collar, selected based on available MI signal strength at the collar and/or likelihood of damage of the first end if it is close to the collar, e.g., as shown in FIG. 6. In examples, the second end is closer than 10 cm to the wireless device 104, and/or to an MI Receiver of the wireless device 104 (specifically aligned to and/or close to a receiver magnetometer in/of the MI Receiver), including closer than 5 cm, closer than 3 cm, closer than 2 cm, closer than 1 cm, or closer than 0.5 cm, e.g., with the separation defined by an adaptor described herein with reference to FIGS. 4A to 4D. The MI Receiver/receiver magnetometer may be housed inside the wireless device 104 with a substantial fraction of the separation between the second end and the MI Receiver/receiver magnetometer, e.g., between 2 cm and 3 cm, e.g., 2.5 cm. Alternatively, the second end may overlap with the MI Receiver/receiver magnetometer, e.g., by surrounding the MI Receiver/receiver magnetometer, as described herein with reference to FIGS. 4E and 4F.

The extension system 102 can mitigate deleterious effects of in-hole MI signal attenuation caused by certain mine geology, in which the MI signal is attenuated so rapidly inside a hole that it renders a very weak MI signal and a very low signal-to-noise ratio (SNR) at the wireless blasting-related device 104. Even if the MI signal reception is strong at the collar, it can be attenuated very quickly deeper in the hole, and having the MI Transmitter 106 too close to the hole may increase the risk of equipment damage during the blast, thus rendering the system commercially unviable. The extension system 102 may substantially increase the distance over which MI signals can be transmitted from the MI Transmitter 106 of the WEBS 100 to the wireless blasting-related devices 104, and potentially transmission of device-sourced MI signals from the wireless blasting-related devices 104 to an external MI signal receiver of the WEBS 100 configured to receive the device-sourced MI signals (e.g., co-located with the MI Transmitter 106 or otherwise towards the first end of the extension system 102).

The extension system 102 may be electrically disconnected or “contactless” from the rest of the WEBS 100. The extension system 102 may be electrically “contactless” by being electrically isolated from the circuitry of the MI Transmitter 106 and/or of the wireless blasting-related device 104—i.e., isolated from the electronic circuitry driving the MI Transmitter 106 and from the control and communication circuits of the wireless device 104—by coupling to the MI Transmitter 106 and to the wireless device 104 using the MI signals, i.e., magnetic flux, rather than connecting electrically and/or through any significant hardware modification of the MI Transmitter 106 or the in-hole wireless devices 104, which could be more dangerous for operators and/or more prone to damage/dirt/fouling in the mine environment (and/or more expensive and error prone). In addition, by coupling though the magnetic flux, the extension system 102 may be used to extend the MI range locally, e.g., in boreholes distant from the MI Transmitter 106, thus generally allowing normal operation of the MI Transmitter 106 and allowing the rest of the WEBS 100 to communicate with other wireless blasting-related devices 104: this allows use of the extension system 102 to be optional to the overall WEBS 100, thus it only needs to be used where a range extension is required.

### High Conductivity Elongated Element

The elongated element may include at least one electrical conductor configured to carry electrical signals that represent the (input) MI signals along the elongated element in or on the electrical conductor.

The extension system 102 may include a first element configured to be coupled to a first end of the elongated element. The extension system 102 may include a second element configured to be coupled to a second end of the elongated element, where the second end is opposite the first end. The first element is configured to be placed towards a first end of the pathway (e.g., towards or proximate to the collar of an example borehole). The second element is configured to be placed at a second end of the pathway (e.g., substantially proximate to a wireless blasting-related device in the example borehole). The first element and the second element may be referred to as ‘terminations’, i.e., first termination and second termination respectively, because they are used at respective ends of the elongated element.

The wireless blasting-related device 104 (or “wireless device”) may be a wireless initiation device, a wireless MI signal survey device, a device with wireless transmitting/receiving capability, or a wireless blast monitoring-and-tracking marker.

The first element is configured to receive the (input) MI signals from the MI Transmitter 106 through the intervening media (e.g., air, water, solid material or a mixture thereof) at a start of the pathway where the MI signal is stronger (than at the end of the pathway). The first element is configured to convert the received MI signals into the electrical signals for the elongated element.

The second element is configured to receive the electrical signals from the elongated element. The second element is configured to convert the electrical signals to generate MI signals, and to transmit these generated MI signals to the wireless blasting-related device 104. The physical end of the range extension system may be defined by an end of the second element that is opposite the elongated element, e.g., facing away from the elongated element and towards the wireless blasting-related device.

The extension system 102 is configured such that the MI signals from the MI Transmitter 106 are coupled through the intervening media (e.g., air, water, solid material or a mixture thereof) to the wireless device 104 more strongly than they would be without the first element, the elongated element and the second element in the pathway.

The electrical conductor may include at least one electrical cable 202 (‘cable’), e.g., a transmission line (e.g., coaxial cable) and/or one or more conductive wires. The cable 202 may be inexpensive and easy to uncoil for use in a mine.

The cable 202 is configured to extend from the first element to the second element, and configured to conduct the electrical signals.

The cable 202 may include a pair of electrically conductive wires/conductors, each terminating at the first element and at the second element, as shown in FIG. 2.

At least one cable 202 can be connected to the first element and/or the second element using respective connectors (“cable connectors”). The cable connectors may include off-the-shelf connectors, e.g., BNC, MIL Spec Connectors, Mini-Fit Connectors, or XT Connectors. The cable connectors may include field-deployable rapid electrical connector clips, e.g., as used for connecting I-kon™ detonators to harness or trunk lines, e.g., including insulation displacement contacts for connecting to respective one or more conductors in the cable.

The cable may be a coaxial cable, e.g., a rigid RG58 cable type, or a twin core cable (with parallel side-by-side instead of coaxial conductors), e.g., an electronic harness wire. The cable may have strong braiding and a thick cable jacket to prevent breakage. The electrical resistance of the cable may be small, thus minimising signal loss in the cable. The cable may be configured/selected to allow for mechanical and electrical connection of the first element and/or the second element at an intermediate point of a length of the cable, e.g., if there are multiple instances of the first element and/or the second element attached to one cable, e.g., as in the branching/collection/distribution network described hereinafter: for example, it may be preferable to use twin core cable instead of coaxial cable because the twin core cable may allow for improved access to the conductors at multiple points along the cable compared to coaxial cable. Selection of exemplary cables may include selection of cable properties including electrical conductivity (or low resistivity) to be less than 5%, less than 2.5%, or less than 1% of the resistance of the first element and the second element. For example, the first element and the second element may be DRX coils with resistances of substantially 450 Ohm each, so the combined end-element resistance may be substantially 900 Ohm, so a cable resistance below 5 Ohm or below 2.5 Ohm may be selected (e.g., 50 m RG58 cable). The electrical signals may travel in the elongated element by modulation of electromagnetic waves (in the transmission line) and/or electrical current (in the wires) in the cable. The electrical signals may include one or more frequencies (“MI frequencies”) that are in the MI signals—in both the input MI signals and the generated MI signals that are based on and correspond to the input MI signals. The MI frequencies include at least one MI frequency from 300 Hz to 3000 Hz (which may be referred to as being in the “ultra low frequency” band designated by the International Telecommunication Union (ITU)) and/or from 3 kHz to 30 kHz (in the “very low frequency” designated by the ITU) and/or from 30 kHz to 300 kHz (in the “low frequency” designated by the ITU), which may include at least one frequency below 9,000 Hz, below 30 kHz, or below 300 kHz, including at least one frequency between 1 kHz and 10 kHz, between 1 kHz and 2 kHz, between 2 kHz and 3 kHz, between 3 kHz and 4 kHz, between 3 kHz and 5 kHz, substantially equal to 4 kHz, or between 4 kHz and 5 kHz.

As shown in FIG. 2, the first element may include at least one first-end antenna 204 configured to transduce the MI signals from the MI Transmitter 106 into electrical signals in the cable 202. The second element may include at least one second-end antenna 206 configured to transduce the electrical signals from the cable 202 into the MI signals for the wireless device 104. In use, the first-end antenna 204 may be arranged/located at or close to a borehole collar, and thus referred to as a “collar coil”. In use, the second-end antenna 206 may be arranged/located at or close to a wireless device 104 in the form of a wireless initiation device in a primer, and may thus be referred to as a “primer coil”.

The first-end antenna 204 and/or the second-end antenna 206 may each include an antenna coil with the same dimensions and electrical properties. Each antenna coil may have a length of substantially 3 cm, an average diameter of substantially 2 cm, substantially 4800 turns, and/or a high permeability core (i.e., a “magnetic core”, e.g., a ferrite rod) in its centre, i.e., a magnetic core inside each antenna coil to substantially increase the antenna coil inductance. Each antenna coil may be a commercially available antenna coil that is the same as that in the WebGen™ 100 DRX. To minimise loss and maximise efficiency in the extension system 102, each antenna coil may be selected to have: (a) low electrical resistance; (b) a high average diameter; and (c) a high number of turns. Each antenna coil has an average diameter selected to be as large as possible while being less than expected hole diameters (depending on the expected deployments), including less than 10 m or less than 2 m for large holes (tunnels), or less than 1 m, less than 0.5 m, less than 0.1 m, less than 6 cm, less than 4 cm, or less than 2 cm for boreholes. In some embodiments, one or both of the first-end antenna 204 and the second-end antenna 206 may include a large antenna coil, including up to the size of a broadcast loop antenna of the MI Transmitter 106, e.g., up to 40 m average diameter. Each antenna coil is selected to have a high number of turns and small coil resistance. Where the coil size is limited (i.e., fixed diameter and maximum length), the number of turns may be prioritised over small/low resistance (as smaller resistivity generally demands thicker wire gauges). Examples may include 200 turns of 24-gauge wire (American Wire Gauge or AWG24), 600 turns of AWG30, 4800 turns of AWG37, or 6750 turns of AWG40.

In operation, the first-end antenna 204 gathers magnetic flux from the MI Transmitter 106, and by Faraday's law an induced current is generated in the first-end antenna 204 representing the MI communication signals. The induced current forms the electrical signals that travel via the elongated element (e.g., the electrical cable 202) to the second-end antenna 206. The second-end antenna 206 generates magnetic flux representing the induced current to form the generated MI signals (representing the MI signals). The wireless device 104 (including an MI Receiver, including at least one receiver magnetometer) can capture the magnetic flux, and thus the relayed MI signals, from the second-end antenna 206. Little or no distortion need be introduced during the magnetic-flux-to-induced-current conversion at the first-end antenna 204, and later the current-to-magnetic-flux conversion at the second-end antenna 206, thus potentially improving/ensuring fidelity of the relayed MI signals. There may be a conversion loss in each conversion. It may be desirable to position the first-end antenna 204 in an area where the MI signal is strong from the MI Transmitter 106 to improve the signals relayed via the extension system 102 to the wireless blasting-related device 104.

The second element may be configured to fasten mechanically to the wireless device 104. As shown in FIG. 2, the second element may include an adaptor 208 (which may be referred to as a cap, a connector, a tether cap or a tether adaptor) configured to hold the second element aligned to the MI Receiver (including the receiver magnetometer in the form of a receiver coil 210 in the MI Receiver, which can be one of three mutually orthogonal MI antenna coils and/or magnetometers) of the wireless blasting-related device 104 and/or to keep the second element close to the MI Receiver of the wireless blasting-related device 104. The adaptor 208 may be configured to hold the second element positioned/aligned such that the second element is in close proximity to the MI Receiver (e.g., to at least one receiver magnetometer, which can be an MI antenna coil, of the wireless blasting-related device), and/or such that the second element is oriented with respect to the MI Receiver (e.g., to the at least one receiver magnetometer of the wireless blasting-related device, e.g., the receiver Z-axis coil) to align magnetic flux from the second element with the MI Receiver (e.g., with the receiver Z-axis coil), e.g., such magnetic flux couples substantially from the second element to the MI Receiver/receiver magnetometer. The physical end of the range extension system may be defined by an end of the adaptor that is opposite the elongated element, e.g., facing away from the elongated element and towards the wireless blasting-related device 104, including the physical end is coupled to/directly contacting the wireless blasting-related device, and when the adaptor 208 is not directly coupled to the wireless blasting-related device 104. The second element may be closer than 10 cm to the MI Receiver/receiver magnetometer of the wireless device 104, including closer than 5 cm, closer than 3 cm, closer than 2 cm, or closer than 1 cm, or closer than 0.5 cm. The second element may be positioned/aligned in sufficient proximity and alignment with the MI Receiver/receiver magnetometer without necessarily directly coupling/attaching the second element/extension system 102 with/to the wireless blasting-related device 104; in other words, detachment of the second element/extension system 102 from the coupling arrangement of the wireless blasting-related device 104, while remaining substantially in alignment with, and within a communication distance with or a distance from, the MI Receiver/receiver magnetometer (receiving antenna) can reduce, but not abolish the communications: this flexibility in placement of the extension system 102 relative to the wireless blasting-related device 104 may be advantageous in some implementations.

When the second element includes the adaptor 208, an apparatus including the first element, the elongated element and the second element may be referred to as a ‘tether’, i.e., a tether for the wireless blasting-related device 104, because it mechanically tethers the wireless blasting-related device, and can be used for lifting/lowering/suspending/pulling the wireless blasting-related device, e.g., in a borehole.

As shown in FIGS. 3B and 4B, the adaptor includes material around the first-end antenna 204, e.g., rigid polymer, that acts as a holder 304 (“first holder” or “housing”) around the first-end antenna 204 to protect the first-end antenna 204 and a first-end portion of the cable 202 inside the first holder 304 from impacts during use. As shown in FIGS. 3B and 4A, the adaptor includes material around the second-end antenna 206, e.g., rigid polymer, that acts as a holder 404 (“second holder” or “housing”) to protect the second-end antenna 206 and a second-end portion of the cable 202 inside the holder 404 from impacts during use. The adaptor 208 may include a first adaptor 208A, which includes, as shown in FIG. 3B: a device lock cap 402 configured to fasten to (or lock to) the wireless device 104 (e.g., a commercially available tether lock cap for a WebGen™ DRX), and a holder 404 configured to receive and hold the second element (specifically the second-end antenna 206 and at least a portion of the cable 202) to maintain the selected alignment and separation between the second element and the MI Receiver/receiver magnetometer, and to secure the second-end antenna 206 and second end of the cable 202. The wireless device 104 may extend a substantial fraction of the separation between the second end in the first adaptor 208A and the MI Receiver/receiver magnetometer, e.g., between 2 cm and 3 cm, e.g., 2.5 cm, such that the second element cannot be applied to the end of the wireless device 104 any closer to the receiver coil 210.

As shown in FIG. 4A, the second holder 404 may include a channel 406 that holds the second-end portion of the cable 202 inside the second holder 404, e.g., including a plurality of turn radii 408 (referred to as “corners”, e.g., substantially right-angled) to guide the cable 202 from the second-end antenna 206 to a substantially central exit point on a face of the second holder 404 that faces away from the wireless device 104 when in use so the cable 202 can be conveniently used to lift the wireless device 104 when in use. The corners 408 and an average diameter of the channel 406 are selected to retain the cable 202 in the second holder 404. The second holder 404 may be formed of two matching halves (e.g. mirror halves), one of which is shown in FIG. 4A, that couple and cooperate to form the channel 406 around the cable 202.

As shown in FIG. 4B, the first holder 304 may include a channel 306 that holds the first-end portion of the cable 202 inside the holder 304, e.g., including a plurality of corners 308 (e.g., substantially right-angled) to guide the cable 202 from the first-end antenna 204 to a substantially central exit point on a face of the first holder 304 that faces away from the first-end antenna 204 when in use so the cable 202 can be conveniently used to lift the first-end antenna 204 when in use. The corners 308 and an average diameter of the channel 306 are selected to retain the cable 202 in the first holder 304. The first holder 304 may be formed of two matching halves, one of which is shown in FIG. 4B, that couple and cooperate to form the channel 306 around the cable 202.

As shown in FIGS. 4C and 4D, the holder 404 (with the cable 202 and the second-end antenna 206 held therein) can be inserted end-on into the device lock cap 402 (e.g., manually or by a machine as part of the deployment operation), which is in place, secured to the wireless device 104.

The adaptor 208 may include a second adaptor 208B, which includes, as shown in FIGS. 4E and 4F: the second-end antenna 206 configured to have a diameter larger than an outer diameter of a housing of the wireless device 104 that is around the MI Receiver/receiver magnetometer, such that the second adaptor 208B can be inserted end-on onto an end of the wireless device 104 that includes the MI Receiver/receiver magnetometer, e.g., manually or by a machine as part of the deployment operation.

The extension system 102 may include at least one frequency-tuning circuit with a tuning capability (e.g., an electronic tuning circuit) to control (or tune) the resonant frequency of the extension system 102 to match the modulation frequency of the MI signals. The tuning of the frequency-tuning circuit(s) can reduce conversion loss in the antennae 204, 206.

The resonant frequency of the extension system includes the one or more “MI frequencies” described hereinbefore, e.g., 1.82 kHz or substantially 2 kHz, 3 kHz or 4 kHz. The frequency-tuning circuit is electronically coupled to the first-end antenna 204 and the second-end antenna 206 and to the cable 202 to tune the resonant frequency of the extension system 102.

The frequency-tuning circuit may include a first-end tuning element, e.g., in the form of a capacitive element (e.g., a first capacitor 212), connected in series or in parallel with the first-end antenna. The frequency-tuning circuit may include a second-end tuning element, e.g., in the form of a capacitive element (e.g., a second capacitor), connected in series or in parallel with the second-end antenna. The capacitors (first capacitor 212, second capacitor) may be arranged electronically in parallel with the respective antennae to increase the total capacitance of the frequency-tuning circuit, or in series to reduce the total capacitance.

As shown in FIG. 2, the circuit including antennae 204,206 and the cable 202 may be tuned to the resonant frequency with one tuning capacitor 212.

In an example implementation, the frequency-tuning circuit included a 3 terminal connector (for example, MT-30 connector) with: terminal A-B connect to the coil of the first-end antenna 204; terminal B-C connected to the tuning capacitor 212; and terminal A-C connected to the electrical cable 202 so that the electrical cable saw the frequency-tuning circuit and the first-end antenna 204 as an inductor L in series with a capacitor C.

The capacitance values of the frequency-tuning circuit may be selected based on the cable length. The cable 202 has parasitic capacitance and inductance depending on the length of the cable, so the value of the tuning capacitor may be selected based on the inductance of the antenna 204, 206 and the parasitic capacitance/inductance of the cable 202. For example, a high inductance coil such as DRX coil will have total inductance of 800 mH, so these coils at both ends of the cable 202 will have 1.6 H total inductance (as the two 800-mH coils in series form a total inductance based on the sum of the inductance values, and 800 mH+800 mH=1,600 mH or 1.6 H), and this will require a quite small tuning capacitance of 4 nF for resonance at 1.8 kHz. As for the cable 202, 1 m of RG58 cable introduces about 25 pF, so an extra 50 m will introduce 1.25 nF, and this will be a significant number relative to the 4 nF of the tuning capacitor, so the tuning capacitor is adjusted by reducing it by the amount of capacitance introduced by the additional cable length, i.e., from 4 nF to (4−1.25=) 2.75 nF. If a lower inductance coil is used, the required tuning capacitance can then be larger, and the resonant frequency is less susceptible to changes in parasitic capacitance/inductance due to changes in cable length, thus there may be no need to readjust the tuning cap due to the additional cable length.

The electronic tuning circuit may include at least one tuneable capacitor (e.g., manually tuneable) to tune the resonant frequency during use (e.g., manually), i.e., during installation of the extension system 102 achieved by selecting a cable length based on the installation arrangements, and then selecting/tuning the tuneable capacitor appropriately to reach the resonant frequency. In some embodiments, one tuning capacitor may be sufficient to tune the circuit, and more tuning capacitors may add complexity and potential tuning error, e.g., due to error tolerance and/or instability of the capacitors, especially manually tuneable capacitors.

As shown in FIGS. 3A and 3B, the first element may include: a first-end projection 302 (e.g., a rigid rod or a flexible rod or flexible rope, e.g., a ferrite rod) with high magnetic permeability configured to confine and guide the MI signals to the first-end antenna 204 from the MI Transmitter 106 through the intervening media (e.g., air, water, solid material or a mixture thereof); and the first holder 304 to hold the first-end projection 302 aligned coaxially with the first-end antenna 204, and/or at least partially inside the coils of the first-end antenna 204 (acting like a magnetic core). The first-end projection 302 extends outwards away from the first element in a direction away from the side from which the cable 202 extends when in use. The first-end projection 302 includes one or more high permeability materials, e.g., a metal, a ferromagnetic material, a paramagnetic material, ferrite, iron, Permalloy, electric steel, stainless steel, carbon steel, aluminium, and alloys thereof. The term “high permeability” as used herein may refer to a permeability higher than that of surrounding media between the first end and the second end (e.g., air, water, solid material or a mixture thereof), i.e., higher than about 1.26 micro H/m. The permeability of the first-end projection 302 may be selected to be as high as possible, e.g., limited by cost, e.g., with a relative permeability above 2, or above 10, e.g., substantially equal to 13. In some implementations, the first-end projection 302 may be replaced with a long first-end projection 302a, shown in FIG. 3A next to the (shorter) first-end projection 302. It may be preferable to have the length of the first-end projection 302,302a as long as possible to attract more flux from the nearby environment, while not being too long to break while in use.

The first-end projection 302 is smaller in diameter than the first-end antenna coil. The rigid rod may be fragile, e.g., made of ferrite, limiting its length to about 15 cm to 20 cm maximum. The flexible rod or flexible rope may be less fragile and more flexible, e.g., embedded with the high permeability material and/or coated with the high permeability material, e.g., extending out of the hole. The first-end projection 302 can guide the MI signals to and from the first-end antenna 204 regardless of the precise length of the first-end projection 302: e.g., the first-end projection may be cut to a shorter length during use, e.g., when being placed in a borehole, and still assist by guiding MI signals along its high-permeability pathway. In an experimental example, a first-end projection 302 including a ferrite rod improved the SNR detected by the first-end antenna 204 by around 9 dB.

In an experimental example, the extension system 102 boosted in-hole signal reception, down a 25 m borehole, from undetectable to above 40 dB of SNR, e.g., as shown in FIG. 14. In this example, the measured signal-to-noise ratio (in dB) was substantially constant as a function of depth in the borehole with the extension system (as shown in FIG. 14 by circles for measurements, and a solid line connecting the circles showing an estimated trend), whereas the measured signal-to-noise ratio (in dB) reduced substantially with depth in the borehole without the extension system (as shown in FIG. 14 by crosses for measurements, and a dotted line connecting the crosses showing an estimated trend). FIG. 14 also shows that the expected performance of the extension system was substantially constant as a function of depth if the measurement conditions had been constant (as shown in FIG. 14 with a dot-dash line), i.e., the dip in the measured SNR between 4 and 10 m depth in FIG. 14 was due to measurement conditions changing rather than increased loss in the extension system. The SNR received by the MI Receiver in the hole with the extension system connected would be substantially independent on the length of the cable 202, and thus of the depth of the wireless device 104 in the hole. For the experiment in FIG. 14, the example first-end antenna 204 (“collar coil”) position was slightly different in each measurement, and the electronic tuning circuit was configured for 5 m of cable 202; so when used with 20 m of cable, without tuning the electronic tuning circuit, the performance of the extension system 102 was degraded. In experimental examples, the reliable working range of an example MI Antenna 107 (a WebGen™ 100 Quad Loop antenna) was extended from 0 m workable range to 48 m with the use of the example extension system placed with its first end at the collar of the borehole (e.g., using 25 m to 50 m of RG58 cable, a 2.4 nF or 2.2 nF ceramic tuning capacitor and DRX coils).

The WEBS 100 may include a plurality of the extension system 102, and/or the extension system 102 may include a plurality of the first elements and/or the second elements connected to one elongated element (as described further hereinafter). When a plurality of the first elements or the second elements are in proximity, e.g., in a borehole, the system includes mutual spacing between adjacent ones of the first elements and second elements. The mutual spacing is selected/dimensioned to be substantially the size of the first elements (e.g., antenna diameter) to substantially mitigate magnetic interference between the adjacent ones of the first elements (first-end antennae) that can de-tune one or more of the first elements (first-end antennae). For example, as shown in FIG. 5, for the DRX coils of about 3 cm in size, there is at least a 3 cm separation.

The WEBS 100 may include a plurality of the extension systems 106 configured to extend to mutually different lengths along the pathway (e.g., into the borehole)—i.e., multiple elongated elements in one borehole at mutually different depths/lengths.

To provide bidirectional (2-way) MI communication, the WEBS 100 may include: a device-based MI signal source with a device-based antenna in the wireless blasting-related devices 104 (to generate the device-sourced MI signals); and the external MI signal receiver (e.g., co-located with the MI Transmitter 106 or otherwise towards the first end of the extension system 102). The external MI signal receiver may include a set of magnetometers. The second element and at least one second-end antenna 206 may be configured to transduce the device-sourced MI signals from the wireless device 104 into device-sourced electrical signals in the cable 202. The first element and at least one first-end antenna 204 may be configured to transduce the device-sourced electrical signals from the cable 202 into the device-sourced MI signals for the external MI signal receiver.

The first end and the second end of the extension system may be interchangeable, i.e., both the first element and the second element may include matching antennas (in size, number of turns, and conductivity), so the extension system may be just as efficient at providing an improved pathway for MI signals in either direction along the elongated element.

### High-Power System

In some embodiments, the extension system 102 may be referred to as a “high-power system” or “high-power tether” or “power tether”. In these embodiments, the first-end antenna 204 is formed of a first-end portion of the cable 202 arranged around the MI Antenna 107, and/or the second-end antenna 206 is formed of a second-end portion of the cable 202 arranged in a coil with a plurality of turns around a frame or drum or bobbin, e.g., formed of plastic. In these embodiments, the MI signals may include relatively higher power signals that deliver sufficient magnetic power to the wireless blasting-related device 104 for the MI signals to be detected, even if, e.g., as shown in FIG. 7, the second-end antenna is not in the borehole or adjacent/attached/tethered to the wireless device 104. As shown in FIG. 7, the first-end antenna 204 is placed next to/around/on the MI Antenna 107 of the MI Transmitter 106 in an alignment and position of high flux, e.g., as close as possible to the WG100 Quad Loop antenna (e.g., affixed to/wrapped around the MI Antenna 107), so that the first-end antenna 204 can absorb as much magnetic flux produced from the MI Transmitter 106 as possible. The first-end antenna 204 (which in these embodiments may be referred to as a “Transmit Coil”) induces a strong current, which is carried by the cable 202, which includes an electrical cable (e.g., a high power rated electrical cable) with at least two conductors (as shown in FIG. 7), to the second-end antenna 206 (which in these embodiments may be referred to as a “Relay Coil”), which can be positioned separated (e.g., along a line of sight or otherwise) from the first-end antenna 204 by a MI absorbing material 704 (including rock types that may exhibit high magnetic-susceptibility or conductivity, e.g., magnetite, rendering traditional MI TTE unreliable). The second-end antenna 206 may be a disposable antenna and a low-cost antenna that can be placed as close as possible to the blasthole or borehole 702. The current circulating inside the second-end antenna 206 produces a secondary flux that is to be picked up by the wireless device 104 in the vicinity, including in the borehole 702.

This “high-power” extension system 102 can be arranged with embodiments of the extension system 102 that are configured to extend into or fit inside the borehole 702 (“in-borehole” embodiments) such that the secondary flux from the “high-power” second-end antenna 206 is directed to and couples into a first-end antenna 204 of the in-borehole extension system 102, which in turn relays the MI signal deeper into the borehole 702 to the wireless device 104. The first-end antenna 204 may include a plurality (e.g., 5) loops of cable tied/attached/fastened around/to the MI Antenna 107 (e.g., to one loop of the Quad Loop) to form the Transmit Coil, thus the coils of the “power tether” first-end antenna 204 can be formed manually on site by manually winding one or more turns/loops of the electrical cable (which may have only conductor) around the flux path of the MI Antenna 107. The second-end antenna 206 may include a wooden or plastic frame or drum, around which is wrapped the second-end portion of the cable 202, e.g., a drum wound with substantially 100 m, 200 m, 300 m, or more of electrical cable (e.g., a commercially available electrical cable wound on drum) to form the Relay Coil. The coil of the Relay Coil may be formed of a commercially winding that is pre-wound with the plurality of turns, e.g., around the frame or drum or bobbin. The cable 202 may include around 70 m, or 150 m of electrical cable (e.g., the commercially available electrical cable). The tuning circuit may include a high power capacitor bank. The length of the cable 202 may be varied substantially, e.g., by around 100 m, without changing the tuning capacitance because the parasitic capacitance of the cable 202 is low compared to the capacitance of the tuning circuit. In an experiment, operating an example the Quad Loop resulted in 12 Amp RMS (root mean square average current) running through the cable 202.

The “high-power” embodiments of the extension system 102 may be used outside boreholes, as shown in FIG. 7. The “high-power” embodiments can carry higher power signals. As described, in the “high-power” embodiments, the second-end antenna 206 can be disposable and low cost for deployment directly beneath or at the blasthole(s) 702, e.g., formed of a low-cost off-the-shelf drum (e.g., RG59). The disposable second-end antenna 206 may be useful for certain mining/automation applications. In the “high-power” embodiments, the first-end antenna 204 may be formed of a few turns of the electrical cable, attached as a winding (but not electrically) to the MI Antenna 107 (e.g., WG100 antenna).

### Branching/Collection/Distribution Network

In some embodiments, the extension system 102 may include a plurality of the first element and/or a plurality of the second element coupled to the elongated element (to share transmission of the electrical signals, or the magnetic signals for the high permeability guide described hereinafter, along the elongated element) thus forming a branching/collection/distribution network (i.e., a branching pathway) of the MI signals by the elongated element including a plurality of elongated branches with respective second ends connected to the first end to emit/transmit the MI signals from the second ends, and/or with respective first ends receive the MI signals.

As shown in FIG. 15, the cable 202 may form the network by being connected to a plurality of branch cables 1504A,1504B,1504C,1504D (forming branches) with respective first-end antennae 204A,204B and second-end antennae 206A,206B connected conductively to the cable 202 using conductive connections 1502, e.g., soldering and/or electrical junctions and/or clips and/or insulation-displacement-contacts. In other words, the extension system 102 may form the network that collects the magnetic flux from a plurality of the first ends, and/or distributes the magnetic flux to a plurality of the second ends, via one cable 202 connected to the plurality of the first ends and the plurality of the second ends (which can be arranged proximate to a plurality of respective wireless devices 104).

As shown in FIG. 15, the cable-based branching/collection/distribution network 1500 can include:
a. a plurality of first-end antennae 204A,204B, each connected to the cable pair 202 by a corresponding branch cable 1504A,1504B, each of which includes a pair of conductors to connect a first terminal 1506A,1506B (which may be designated “positive” or “negative” depending on the direction of the applied magnetic flux and the coil windings) of each first-end antenna 204A,204B to a first conductor 1508 of the cable 202 and to a connect second terminal 1510A, 1510B (opposite from the first terminal 1506A,1506B) to a second conductor 1512 (not electrically connected to the first conductor 1508 except via the antennae 204A,204B,206A,206B) of the cable 202; and/or
b. a plurality of second-end antennae 206A,206B, each connected to the cable pair 202 by a corresponding branch cable 1504C,1504D, each of which includes a pair of conductors to connect a first terminal 1506C,1506D of each second-end antenna 206A,206B to the first conductor 1508 of the cable 202 and to a connect second terminal 1510C,1510D (of opposite charge from the first terminal 1506C,1506D) to the second conductor 1512 of the cable 202; and
c. a plurality of the conductive connections 1502 that connect the branch cables 1504A,1504B,1504C,1504D (and pair of conductors therein) to the cable 202 (and pair of respective conductors 1508,1512 therein); and
d. the cable 202.

The cable-based network 1500 may be configured to include just one of the first-end antennae 204A, 204B and a plurality of the second-end antennae 206A, 206B arranged proximate to the respective wireless devices 104 and/or boreholes.

In the cable-based network 1500, each first-end antenna 204A, 204B includes a first-end tuning element (which can be a capacitive element, e.g., a first capacitor 212) connected in series or in parallel with the first-end antenna 204A, 204B, e.g., in series as shown in FIG. 15. Each first-end tuning element can be tuned such that the resonant frequency of the first-end antennae 204A,204B and the network 1500 is substantially equal to the receive MI frequency of the wireless devices 104 that are being addressed by the second-end antennae 206A,206B such that adding or removing ones of the first-end antennae 204A,204B (and/or adding or removing ones of the second-end antennae 206A,206B) does not detune the entire cable-based network 1500 resonant frequency from the receive MI frequency, at least when stray capacitance introduced by the cable 202 is negligible compared to the capacitance of the first-end tuning elements. Accordingly, ones of the first-end antennae 204A, 204B and/or the second-end antennae 206A, 206B can be added to the cable-based network 1500, or removed from the cable-based network 1500, without having to move/disturb other elements of the cable-based network 1500. For example, an additional second-end antenna 206A, 206B can be added to direct flux to an additional borehole without having to move the cable 202.

The network 1500 may provide for improved redundancy and reliability. For example, ones of the first-end antennae 204A,204B and/or the second-end antennae 206A,206B can be damaged/rendered non-operational while allowing the network 1500 to continue functioning if even one of the first-end antennae 204A,204B and one of the second-end antennae 206A,206B remain operational and connected to the cable 202. For example, if multiple first-end antennae 204A, 204B (“collar coils”) are placed at mutually different respective depths into the collar of a borehole, e.g., one at 1 m, another one at 2 m, and another one at 3 m, and if, due to back break, the collar coils at 1 m and 2 m are consumed, there will still be a collar coil at 3 m to receive the MI signal, thus providing redundancy of the second ends.

The network 1500 may provide for improved MI signal scalability. For example, an additional first-end antenna 204A,204B can be added to capture more magnetic flux to direct into the cable 202 if more signal strength at the second-end antennae 206A,206B is required. Being able to attach multiple first-end antennae 204A, 204B (“collar coils”) to the cable 202 allows for scaling of the induced current inside the cable 202. If all the collar coils have the same the winding orientation, and are connected to the central cable pair in a way that their induced currents are in-phase, having two collar coils, if receiving the same amount of magnetic flux each, will increase total induced current by 2, and thus the signal strength by 3 dB.

When using the network 1500, only one elongated element (i.e., cable 202) may need to be arranged in the mine to provide MI flux to a plurality of the second-end antennae 206A,206B which can be in different locations, e.g., separated into different boreholes or at different depths in a borehole.

### High Conductivity Guide

In some embodiments, the extension system 102 might include the electrical conductor without the first element and the second element required by coupling the input MI signals directly into an induced current in the electrical conductor by Faraday's law, e.g., without the antennae. This elongated element may be referred to as a “high conductivity guide” or a “high conductivity hose”. The high (electrical) conductivity guide may still enhance transmission of the MI signals along its length by induction of the current along the electrical conductor without the need for the first element and the second element. The high conductivity guide includes and/or consists substantially of a conductive medium, e.g., a metal conductor/member/rod/rail/pipe/lift shaft/reinforcement mesh/etc. The high conductivity guide receives a modulated induced current Ic, representing the MI signals, induced at its first end by the modulated magnetic flux of the MI Transmitter 106. The induced current Ic along the high conductivity guide is carried to the second end, and the modulation of Ic generates a second-end magnetic field, which can be directed to the wireless device 104. The physical end of the range extension system may be defined by an end of the elongated element (high conductivity guide) that is facing towards the wireless blasting-related device.

### Branching/Collection/Distribution Network

In some embodiments, the high conductivity guide may form a high-conductivity network for the magnetic flux by the high conductivity guide including a plurality of high conductivity guides (forming branches) with respective second ends, each carrying a portion of the induced current Ic, connected conductively to the first end using conductive connections, e.g., welding.

### High Permeability Guide

In some embodiments, the elongated element may include high magnetic permeability material (i.e., material with a relatively high magnetic permeability) to shape/guide the magnetic field into and along the pathway to improve transmission along the pathway, i.e., to provide magnetic flux attraction/concentration. In these embodiments, the elongated element may be referred to as an “an elongated high permeability guide” or high permeability guide 802. The high permeability guide 802 acts like a magnetic core. The MI signals travel in and along the elongated high permeability guide 802 as magnetic signals, i.e., by modulation of a magnetic field (thus magnetic flux) in the high permeability material. The high permeability guide 802 is arranged and configured to carry the MI signals in/on the magnetically permeable material. The magnetically permeable material has a high magnetic permeability (and correspondingly high magnetic susceptibility), at least higher than the surrounding media (e.g., air, earth rock, stemming, soil, concrete, brick and/or water) through which the MI signal is to be conveyed, thus the elongated high permeability guide 802 improves the transmission range of the MI signals. The permeability in Henrys per meter (H/m) of the high permeability material is selected to be higher than the surrounding material at the frequencies in the MI signals described hereinbefore. The high permeability material may include one or more of: a metal, a ferromagnetic material, a paramagnetic material, ferrite, iron, Permalloy, electric steel, stainless steel, carbon steel, aluminium, and alloys thereof, and/or a superconductor, e.g., a magnetic hose that uses a ferromagnetic and superconductor axial sandwich arrangement. Alternatively or additionally, the high permeability material may include a high permeability composite material in the form of a magnetic field permeable composite, wherein the magnetic field permeable composite includes a binder material and a magnetisable material. The magnetic field permeable composite presents a solid mass throughout which the magnetisable material is distributed, so the binder is solid in use, but the binder may have a pourable or mouldable composition that subsequently cures or solidifies into the solid form of the composite present in the high permeability material—the magnetic field permeable composite may therefore be advantageously used in forming certain portions of the elongated element, e.g., portions with bends/corners or other selected geometric shapes that allow passage of the magnetic flux along the elongated element while minimising loss from the elongated element between its ends. The binder material may include polymer, cement, plaster and/or bitumen. The polymer may include epoxy resin, polyester resin, polyurethane resin, silicone resin, polyolefin, polyamine and/or polyester. The cement may include hydraulic and/or non-hydraulic cements. In embodiments, the cement may include Portland cement, Portland cement blends, pozzolan-lime cement, slag-lime cement, supersulfated cement, calcium sulfoaluminate cement, geopolymer cement and/or Sorel cement. The magnetisable material may include iron, nickel, zinc, manganese, strontium, barium, chromium, cobalt and/or gadolinium (which are elements), and/or oxides or oxyhydroxides of any one or more of the aforementioned elements, and/or mixtures/alloys of any of the aforementioned elements/oxides/oxydydroxides. The magnetisable material may include ferrite, and the ferrite may comprise Fe2O3 blended with one or more elements selected from strontium, barium, manganese, nickel and zinc. The magnetisable material may include manganese-zinc ferrite, nickel-zinc ferrite, or a combination thereof. The magnetisable material may include particles having a largest dimension ranging from about 0.5 mm to about 20 mm, or from about 1 mm to about 10 mm, and/or a polydisperse particle size. The magnetisable material may be substantially anisotropic. The composite may comprise at least about 30 wt. % or at least about 40 wt. %, or at least about 50 wt. %, or at least about 60 wt. %, or at least about 70 wt. %, or at least about 80 wt. % magnetisable material. The composite may comprise at least about 20 wt. %, or at least about 30 wt. %, or at least about 40 wt. %, or at least about 50 wt. %, or at least about 60 wt. %, or at least about 70 wt. % binder material. The high permeability composite material may have a relative magnetic permeability (μᵣ) of at least 2, or at least 5, or at least 10, at least 15, or at least 20, or at least 25, at least 30, or at least 35, at least 40, or at least 45, or at least 50. The magnetisable material may be presented within the composite material such that it does not produce an electrically conductive network of the magnetisable material. For example, the magnetisable material will generally not be used at a concentration that results in a substantive portion of the particles of magnetisable material being in contact with each other so that the particles will be separated by at least a portion of the binder matrix; alternatively, a concentration of magnetisable material that results in physical contact of the particles may be used where the particles of magnetisable material are coated with and insulation layer that prevents a conductive network being formed even when the particles of magnetisable material are in contact with each other. A concentration of magnetisable material that results in physical contact of the particles may also be used where the particles of magnetisable material are not themselves electrically conductive. The high permeability composite material may include a product such as MC40™ (sold by Magment GmbH) that comprises a cement binder and magnetisable material. The permeability of the high permeability material may be selected to be as high as possible, e.g., limited by cost, e.g., with a relative permeability above 2, or above 10, e.g., substantially equal to 13; whilst being compatible to application in the relevant use environment. The physical end of the range extension system may be defined by an end of the elongated element (high permeability guide) that is facing towards the wireless blasting-related device.

The elongated high permeability guide may extend in length, for example, in underground mining, from a point on the surface or underground, through the earth, to a location able to express the generated MI signals, so that they can be used to communicate with desired devices. In surface mining, or other applications, this elongated high permeability guide may run across the surface for at least part of its path, in order to extend the MI signals. The length of the elongated element may be from 50% to 500% of the theoretical MI signal range of the selected transmission system, in the absence of the elongated element. For example, if the theoretical transmission range of an antenna is a radius of 150 m, then the elongated element may be 75 m to 750 m long. The high magnetic permeability of the elongated high permeability guide is preferably above that of the surrounding material through which the MI signal should be conveyed. The permeability in Henrys per meter (H/m) of the high permeability material is selected on this basis, considering operation at frequencies in the MI signals, i.e., the “MI frequencies” described hereinbefore.

The high permeability guide, with a length substantially higher than its cross-sectional diameter, may be described as shaping the magnetic field into and along the path to improve transmission along the path.

The high permeability guide 802 may be formed of a cord/rope/line coated in the high permeability material and/or embedded with the high permeability material, e.g., a ferrite-based cable. The high permeability guide 802 need not be metal or conductive.

The high permeability guide 802 may be used in place of the electrical conductor/cable 202 if there is a likelihood of impact damage to the elongate element because a similar level of mechanical damage, which is common in some mining environments (especially in blastholes), could impact the electrical conductor more than the high permeability guide 802 (which may be a ferrite-based cable).

As shown in FIG. 8, the extension system 102 may include the high permeability guide 802, without the first element and/or the second element being required, by coupling the MI signals directly into MI signals in the high magnetic permeability material. The high permeability guide 802 may still enhance transmission of the MI signals along its length by providing an improved magnetic transmission pathway compared to the air, rock, soil, water, etc. of the surrounding media 704, without the need for the first element and the second element.

The high permeability guide 802 may have an average cross-sectional diameter, at least at the first end, that is less than the average diameter of the coils of the MI Transmitter 106.

In use, the high permeability guide 802 is arranged and held where the flux of the MI Transmitter 106 is highest, oriented coaxially with the coils of the MI Transmitter 106.

As shown in FIG. 9, high permeability guide 802 may include a plurality of branches 902 that guide the magnetic flux to a respective plurality of second ends. The high permeability guide 802 may thus form a high-permeability branching/collection/distribution network of the magnetic flux, and the second ends may be arranged closer to the boreholes and wireless devices 104 than the MI Transmitter 106, especially when the MI Transmitter 106 has a line of sight to the boreholes blocked by the MI absorbing material 704.

As shown in FIG. 10, the extension system 102 with the high permeability guide 802 may include the second element in the form of a coil pair 1002 to improve and/or shape/control magnetic coupling out of the second end of the high permeability guide 802 (and in bidirectional embodiments, back into the high permeability guide 802). The coil pair 1002 includes: a primary coil 1004 that loops around the high permeability guide 802; a secondary coil 1006 electrically coupled to the primary coil 1004 to share induced current; and a tuning element 1008 (e.g., a capacitor) to tune the resonant frequency of the coil pair 1002 to match the modulation frequency of the MI signals. The primary coil 1004 has an average cross-sectional diameter substantially equal to the average cross-sectional diameter of the second end of the high permeability guide 802 to maximise flux linkages therebetween. The coil pair 1002 allows for selection/tuning/control of the number of turns of the primary coil 1004 and the secondary coil 1006. The coil pair 1002 allows for positioning/placement/orientation of the secondary coil 1006 independently from the high permeability guide 802, constrained only by the coupling between the primary coil 1004 and the secondary coil 1006—which may include a flexible cable, e.g., with the properties of cable 202—so in use the magnetic flux can be directed towards a desired site, and the secondary coil 1006 can be positioned close to/directed towards a selected wireless device 104.

As shown in FIG. 11, the MI Transmitter 106 can be configured to include a custom antenna loop having an average cross-sectional diameter substantially equal to the average cross-sectional diameter of the first end of the high permeability guide 802 to maximise flux linkages therebetween.

As shown in FIG. 12, the extension system 102 can include: the high permeability guide 802 with the plurality of the branches 902; and a corresponding plurality of the coil pair 1002 on the respective branches.

In a simulation example, as shown in FIG. 13A, a magnetic field represented by plurality of magnetic field lines 1302 is established around a simulation 1304 of one of the DRX coils when energised. As shown in FIG. 13B, the magnetic field lines 1302 are extended to have higher field strength along the length of a simulation 1306 of the high permeability guide in the magnetic field of the simulated DRX coil.

### Branching/Collection/Distribution Network

As mentioned above, in some embodiments, the extension system may form a high-permeability branching/collection/distribution network (i.e., a branching pathway) of the MI signals by the elongated element including a plurality of elongated branches with respective second ends connected to the first end to emit/transmit the MI signals from the second ends.

As shown in FIGS. 9 and 12, the high permeability guide 802 may form the high-permeability network of the magnetic flux, and the second ends may be arranged proximate to a plurality of respective wireless devices 104.

### Definitions

The WEBS described herein is configured for assisting commercial blasting by sending magnetic induction (MI) signals to (and/or receiving MI signals from) the wireless blasting-related devices that are deployable or deployed within portions of one or more physical media (e.g., a rock formation) intended to be blasted as part of the commercial blasting operation. Such wireless blasting-related devices include wireless initiation devices positioned in boreholes or blastholes, with which the MI Transmitter communicates as part of enabling/disabling, encoding, querying, (re) programming. (re) synchronizing, and/or controlling the operation, and/or arming, and/or firing of particular wireless initiation devices in association with the commercial blasting operation.

The communication using the MI signal may be referred to as “through the earth” (TTE) communication or signalling, referring to the communication of signals in, through, and/or across a set of physical media residing between the signal source and the signal receiver or detector, e.g., wherein at least one of the signal source and the signal detector is at least partially obstructed, overlaid, covered, surrounded, buried, enclosed, encased by the set of physical media, or otherwise deprived of communication by conventional transmissions. The set of physical media can include one or more of rock, broken rock, stone, rubble, debris, gravel, cement, concrete, stemming material, soil, dirt, sand, clay, mud, sediment, water, snow, ice, one or more hydrocarbon fuel reservoirs, site infrastructure, building/construction materials, and/or other media or materials.

With respect to MI related communication terminology used herein, the terms “magnetic induction based communication,” “MI based communication,” and “MI communication” refer to the generation of a magnetic field, which in various embodiments includes a quasi-static magnetic field, in accordance with a modulation scheme or protocol to wirelessly communicate signals between a MI signal source that generates or outputs the modulated magnetic field and an MI signal receiver that receives or detects such signals, e.g., by way of detecting and decoding the modulated magnetic field. In multiple embodiments, the MI signal source includes an electrically conductive coil or loop antenna, and the MI signal receiver includes a magnetometer. MI based communication can involve, include, or be (a) near-field signal communication, in which the MI signal receiver is located within a near-field region or zone of the magnetic field generated by the MI signal source, wherein magnetic field strength as a function of distance away from the MI signal source decays in accordance with an inverse distance cubed relationship, and the MI signal source detects changes in near-field magnetic flux generated by the MI signal source rather than detecting far-field or radiatively propagated electromagnetic waves (e.g., radio waves) generated by the MI signal source; and/or (b) transition region or zone signal communication, in which the MI signal receiver resides beyond the near-field region or zone of the magnetic field generated by the MI signal source, but resides within approximately one-half of a wavelength away from the MI signal source, and more commonly or particularly resides within approximately 10 skin depths (e.g., less than 10 skin depths), approximately 6-8 skin depths (e.g., less than 8 skin depths), approximately 3-5 skin depths (e.g., less than 5 skin depths), or approximately 2-4 skin depths (e.g., less than 4 skin depths) away from the MI signal source, wherein the near-field inverse distance cubed magnetic field strength decay relationship is modified (e.g., as a result of interaction(s) between near-field and far-field magnetic flux, and/or secondary fields that are induced by way of the physical media in or through which signal communication occurs). Individuals having ordinary skill in the relevant art, e.g., in relation to TTE communication, will understand the meaning or definition of skin depth. It can be noted that skin depth is the same physical property that individuals having ordinary skill in electrical engineering understand with respect to current crowding, e.g., in wires, for alternating current (AC) signals. Individuals having ordinary skill in the relevant art will further understand that in conductive media, an MI signal wavelength will be approximately 2*π*δ, where δ is the skin depth, and hence one-half wavelength is approximately 3.1 skin depths. Typical earth media or materials, e.g., media or materials in/below the ground, can be categorized as conductive in this sense. In view of the foregoing, the transition zone thus exists between the near-field and the far-field zones of the magnetic field generated by the MI signal source; hence, individuals having ordinary skill in the art will recognize that in transition zone communication, even though the MI signal receiver resides beyond or outside of the near-field region of the magnetic field generated by the MI signal source, the MI signal receiver does not reside in the far-field region or zone of the magnetic field generated by the MI signal source. Further in view of the foregoing, with respect to the generation of signals by an MI signal source and the detection of such signals by an MI signal receiver, MI based communication in accordance with various embodiments of the present disclosure can involve, include, or be (i) near-field signal communication, and/or (ii) transition zone signal communication, depending upon embodiment details, a commercial blasting operation under consideration, and/or a commercial blasting environment under consideration. Thus, the MI communication in accordance with various embodiments of the present disclosure occurs or predominantly occurs by way of the generation and detection of variations in a magnetic field, e.g., in a near-field zone or a transition zone as set forth above. The terms “magnetic induction communication signal,” “MI communication signal,” and “MI signal” refer to a signal encoded upon a magnetic field, e.g., a quasi-static magnetic field generated by a magnetic signal source, by way of a modulation scheme or protocol.

Accordingly, the MI signals may be near-field signals and/or transition zone signals that provide downlink MI communication including downlink MI signals to the wireless blasting-related devices. For the near-field signal MI communication, the device-based MI Receiver is located within a near-field region or zone of a magnetic field generated by the MI Transmitter. Magnetic field strength as a function of distance away from the MI Transmitter decays in accordance with an inverse distance cubed relationship, and the device-based MI Receiver may detect changes in near-field magnetic flux generated by the MI Transmitter rather than detecting far-field or radiatively propagated electromagnetic waves (e.g., radio waves) generated by the vehicle-based or broadcast MI signal source. The transition-zone signals can provide uplink MI communication including uplink MI signals from the wireless blasting-related devices to the external MI signal receiver. For the transition region or zone signal MI communication, the external MI signal receiver can be positioned beyond the near-field region or zone of the magnetic field generated by the device-based MI signal source, but within approximately one-half of a wavelength away from the device-based MI signal source, and more commonly or particularly resides within approximately 10 skin depths (e.g., less than 10 skin depths), approximately 6 to 8 skin depths (e.g., less than 8 skin depths), approximately 3 to 5 skin depths (e.g., less than 5 skin depths), or approximately 2 to 4 skin depths (e.g., less than 4 skin depths) away from the device-based MI signal source.

The blasting-related devices are configured to receive, decode and process the downlink MI signals. The receiver magnetometer of the MI Receiver can include a set of electrically conductive coils or loop antennas, with an average diameter of between 0.01 m and 0.3 m, which can corresponding to a diameter of the borehole. The receiver magnetometer of the MI Receiver is a device-based magnetometer, which can be 3-axis magnetometers configured for detecting magnetic flux in 3 mutually orthogonal axes, or single axis (1-axis) magnetometers configured for detecting magnetic flux in 1 orthogonal axis. The single axis (1-axis) magnetometer can be aligned in the blasting-related device for detecting magnetic flux parallel to the lengthwise, longitudinal, or central axis of the blasting-related device. Alternatively, the single axis (1-axis) magnetometer can be aligned in the blasting-related device for detecting magnetic flux perpendicular to the lengthwise, longitudinal, or central axis of the blasting-related device. The downlink MI signals can travel a downlink distance TTE using one or more downlink MI signal frequencies, which can include broadcast MI signal frequencies. The broadcast MI signal frequencies can include the one or more “MI frequencies” described hereinbefore. The broadcast downlink distance can be greater than 100 meters; greater than multiple or many hundreds of meters; between 200 and 900 meters; greater than a kilometre; or greater than multiple kilometres.

The blasting-related devices may be configured to generate, output and transmit the uplink MI signals. The device-based MI signal source can include a set of electrically conductive coil or loop antennas, with an average diameter of between 0.01 m and 0.3 m, which can corresponding to a diameter of the borehole. The device-based MI signal source can be driven at substantially or approximately 3 watts (W). The device-based MI signal source can include a set of coil antennas. The uplink MI signals travel an uplink distance TTE using one or more uplink MI signal frequencies. The uplink distance can be less than 100 meters (“m”); less than 80 m; less than 60 m; between 0.10 m and 60 m; between 0.25 m and 50 m; between 0.50 m and 40 m; or between 1 and 30 m. The uplink MI signal frequencies can include at least one of the at least one “MI frequencies” described hereinbefore.

The blasting-related device can be configured for deployment in a confined space proximate to or in the portion of the physical media. The blasting-related device has a geometry (including shape and size) configured for deployment in the confined space. The confined space can be a hole or borehole, and the geometry can include: a perpendicular width (e.g., diameter for a circular cross section) that is less that a borehole diameter (open diameter of the borehole); and a (longitudinal) length that can be limited by (i) loading manner and optionally (ii) other borehole contents. The device-based MI signal source is configured based on the size of the blasting-related device. The device-based MI signal receiver is configured based on the size of the blasting-related device. The blasting-related device has the power source with an electrical charge storage capacity (i.e., power storage) associated with the size: for example, the blasting-related device can be sized to fit into conventional boreholes, e.g., having an average diameter of substantially 4 to 6 cm (for a smaller embodiment) or substantially 10 to 20 cm (for a larger embodiment) or up to 90 cm (for very large holes), and the power storage can be substantially equivalent to two or four commercially available “AA” size batteries (each of which can have substantially 1000 to 4000 milliampere hours capacity, e.g., substantially 3500 mAh for a lithium AA battery).

The blasting-related devices can include:
one or more initiation devices (i.e., wireless initiation devices);
one or more survey devices (i.e., wireless MI signal survey devices); and/or
one or more markers (i.e., wireless blast monitoring-and-tracking devices).

The device-based MI signal source can be aligned in the blasting-related device for generating a magnetic flux maximum parallel to the lengthwise, longitudinal, or central axis of the blasting-related device when deployed in a borehole.

Alternatively, the device-based MI signal source can be aligned in the blasting-related device for generating a magnetic flux maximum perpendicular to the lengthwise, longitudinal, or central axis of the blasting-related device when deployed in a borehole. The orientation of the device-based MI signal source may be selected by a setting in the blasting-related device and/or automatically to select the direction that generates the strongest signal for the external MI signal receiver.

The initiation devices are devices for giving rise to an explosion or detonation. The initiation devices can be positioned in the boreholes or the blastholes. The vehicle can communicate with the initiation devices using the MI signals, and the downlink magnetic induction (MI) signals may represent enabling/disabling, encoding, querying, (re) programming. (re) synchronizing, and/or controlling operation, and/or arming and/or firing of selected ones of the initiation devices (as part of enabling/disabling, encoding, querying. (re) programming, (re) synchronizing, and/or controlling the operation and/or arming and/or firing of selected ones of the initiation devices in association with the commercial blasting operation).

Each initiation device can include an assigned unique identifier (ID) stored in memory in the initiation device. A group of the initiation devices can include a unique group ID (GID) stored in the memory.

In an embodiment, a wireless initiation device 1000 includes a housing or shell that carries the power source (e.g., the battery and/or the set of capacitors); power management circuitry; at least one control/processing unit providing transistor based circuitry configured for processing instructions/commands, and at least one memory for storing instructions/commands and data; possibly a sensing unit providing a set of sensors configured for sensing or generating signals corresponding to environmental conditions or parameters such as temperature, pressure, vibration, shock, the presence of certain chemical species, light, and/or other conditions or parameters (e.g., in-hole environmental conditions or parameters); an MI based communication unit providing modulation/encoding circuitry coupled to a set of MI signal sources (e.g., one or more coil antennas), and demodulation/decoding circuitry coupled to a set of magnetometers (which can include one or more magnetometers, such as one or more types of magnetometers indicated above, corresponding to one or more orthogonal spatial axes); and an initiation device (e.g., a detonator, or a DDT device), which is configurable or configured for selectively initiating and/or detonating an associated, supplemental, or main explosive charge (e.g., a booster explosive charge) that can be associated with, couplable/coupled to, or contained in the housing or shell.

The blasting-related device can include one or more sensors that detect, monitor, estimate, or measure physical parameters associated with the physical med in which they are deployed. The sensors can include a set of sensors configured for sensing selected environmental conditions or parameters, including temperature, moisture, pressure, and/or shock.

The blasting-related device can include a housing, shell, case, frame and/or support structure that mechanically houses, carries, protects and/or supports at least pressure and water-sensitive elements of the blasting-related device.

The pressure and water-sensitive elements include device-based electronic elements in the blasting-related device. The device-based electronic elements include: the device power source, a device control unit, and the device-based MI based communication unit.

For the initiation devices, the device-based electronic elements include an initiation element (e.g., a detonator). For the initiation devices, the pressure and water-sensitive elements include device-based explosive elements. The device-based explosive elements include a main explosive charge.

The blasting-related devices may be configured for establishing one or more ad-hoc MI-based communication networks among or between each other.

The MI Transmitter may include a current driver providing MI signal modulation circuitry, and the broadcast loop antenna that can be driven by the current driver, configured for generating or outputting broadcast MI communication signals having sufficient strength to be received by the wireless blasting-related devices, e.g., the wireless initiation devices that will be initiated during the blast or blast sequence. The broadcast loop antenna can have an average loop diameter between 1 m and 100 m, or between 1 km and 10 km. The broadcast distance can be greater than 100 meters; greater than multiple or many hundreds of meters; between 200 and 900 meters; greater than a kilometre; or greater than multiple kilometres. The broadcast loop antenna may include a set of WebGen™ 100 Quad Loops.

The MI Transmitter can output, issue, or broadcast a synchronization signal that can be received and processed by each of the wireless initiation devices that will be involved in the blast or blast sequence, optionally including device IDs and/or GIDs.

Each marker (“blast monitoring/tracking device”) is configured for generating or facilitating the generation of signals to identify itself through broadcast of an assigned identifier, and optionally it's position or location that correspond to, indicate, or identify the marker's physical position or location before and/or after the commercial blasting operation.

The plurality of markers are configured to reside in boreholes in which the initiation devices reside, and/or in auxiliary boreholes located proximate to and separate from the boreholes 50 in which the initiation devices reside. The marker can be coupled or attached to an initiation device. The marker can be integrated into an initiation device such that the marker and the initiation device are both within the housing. The marker and the initiation device can be configured to utilize different MI signal frequency bands or frequencies for MI based position localization and MI based communication respectively. The frequencies for MI based identification and position localization may include at least one of the “MI frequencies” described hereinbefore. The marker can include a receive loop with an average diameter from 0.01 m to 1 m; or a fluxgate magnetometer, SQUID magnetometer, AMR magnetometer, or Hall effect magnetometer.

Each marker can be assigned or programmed with its own unique ID. A selected group of markers can be assigned or programmed with a unique GID for that group.

In an embodiment, a blast monitoring/tracking device 1600 includes a ruggedized or highly ruggedized housing that contains (i) a set of magnetic structures, elements, or devices having known magnetic properties detectable by blast support vehicles 100; and/or (ii) at least some of the power source; a control unit providing transistor based circuitry configured for processing instructions/commands, and at least one memory for storing instructions/commands and data; an MI based communication unit providing modulation/encoding circuitry coupled to a set of MI signal sources (e.g., one or more coil antennas), and demodulation/decoding circuitry coupled to a set of magnetometers (which can include one or more magnetometers, such as one or more types of magnetometers indicated above, corresponding to one or more orthogonal spatial axes); and a sensing unit providing a set of sensors configured for sensing or generating signals corresponding to environmental conditions or parameters such as temperature, pressure, vibration, shock, the presence of certain chemical species, light, and/or other conditions or parameters, e.g., in-hole environmental conditions or parameters.

The term “explosive composition” refers to a chemical composition capable of undergoing initiation and producing an explosion in association with the release of its own internal chemical energy. An explosive composition of appropriate type and/or under appropriate physical conditions may further undergo detonation. The terms “explosive material,” and “explosive substance” refer to a material or substance that carries or includes an explosive composition.

The term “initiation” refers to the initiation or triggering of combustion, a deflagration, a deflagration to detonation transition (DDT), or detonation in a material or substance carrying an explosive composition, and the associated formation of different chemical species, or the initiation of chemical reactions that result in combustion and the associated formation of different chemical species in the material or substance. The term “explosive initiation” refers to initiation giving rise to an explosion or detonation, the occurrence of which corresponds to or is defined by at least some of a rapid energy release, volume increase, temperature increase, and gas production or release, as well as the generation of at least a subsonic shock wave. The term “detonation” refers to the generation of a supersonic detonation wave or shock front in an explosive material or substance, in a manner understood by individuals having ordinary skill in the relevant art.

The term “commercial blasting operation” includes the initiation and/or detonation of explosive materials or substances disposed in the physical media, e.g., a geological formation, by way of initiation devices as part of mining, quarrying, civil construction/demolition, seismic exploration, and/or another non-military blasting operation. Such initiation and/or detonation explosively blasts, e.g., fractures and/or heaves, the physical media in which the commercial blasting operation occurs. Such initiation and/or detonation can be referred to as blasting, in a manner readily understood by individuals having ordinary skill in the relevant art. The physical media in which the commercial blasting operation can be anywhere that is intended for physical transformation by blasting, such as a mining environment, e.g., an open cut or underground mine.

The terms “initiation device” and “explosive initiation device” refer to a device configured for initiating and/or detonating an explosive material, substance, or composition as part of a commercial blasting operation. In various embodiments, an initiation device is typically configured to reside within a borehole or blasthole formed or drilled in the physical media in which the commercial blasting operation occurs, where a borehole can be categorized or defined as a typically elongate hole that does not contain or is not intended to contain explosive material(s), or which does not contain or is not intended to contain explosive material(s) and a set of initiation devices configured for the initiation and/or detonation thereof; and a blasthole can be categorized or defined as a typically elongate hole that does contain or is intended to contain explosive material(s), or which does contain or is intended to contain explosive material(s) and a set of initiation devices configured for the initiation and/or detonation thereof. An explosive initiation device can include or be a primer, e.g., a primed booster, in a manner readily understood by individuals having ordinary skill in the relevant art.

The term “wireless blasting-related device” refers to a device configured for deployment near or in a portion of physical media, e.g., a confined space such as a borehole or blasthole formed in the physical media, that is intended to be blasted as part of a commercial blasting operation. A wireless blasting-related device does not require or utilize wires that link the device to a non-local or remote control system or apparatus for the transfer of signals, commands, and data between the wireless blasting-related device and the non-local or remote control system or apparatus. Wireless blasting-related devices in accordance with various embodiments of the present disclosure can be configured for bidirectional or 2-way MI based communication. Wireless blasting-related devices include at least some of wireless initiation devices, wireless MI signal survey devices, and wireless blast monitoring/tracking devices.

The terms “wireless initiation device” or “wireless explosive initiation device” refer to a device typically configured for deployment near or in a portion of physical media, e.g., a confined space such as a blasthole within the physical media, intended to be blasted as part of a commercial blasting operation, which is configured for initiating and/or detonating an explosive material, substance, or composition as part of the commercial blasting operation, and which does not require or utilize wires that link the wireless initiation device to an external control apparatus or controller located remote from the wireless initiation device for the transfer of signals, data, and commands between the external control apparatus or controller and the wireless initiation device, but which rather utilizes MI based communication for such signal, data, and command transfer. In some embodiments, wireless initiation devices can include one or more types of sensors that detect, monitor, estimate, or measure particular physical parameters associated with the physical media in which they are deployed.

The term “MI signal survey device” refers to a device configured for deployment proximate to or within portions of physical media, e.g., a confined space such as a borehole or blasthole within the physical media, intended to be blasted as part of a commercial blasting operation, and which includes a magnetometer (referred to herein as a “survey magnetometer”) configured for measuring or monitoring downlink and/or uplink MI based communication signal strength near or within portions of this physical media at one or more MI signal frequencies.

The terms “wireless blast monitoring device,” “wireless blast tracking device,” and “wireless blast monitoring/tracking device” refer to a device configured for deployment near or in a portion of physical media, e.g., a confined space such as a borehole or blasthole within the physical media, intended to be blasted as part of a commercial blasting operation, and which is configured for generating or facilitating the generation of position or location signals that correspond to, indicate, or identify the device's physical position or location before and/or after the commercial blasting operation. In some embodiments, wireless blast monitoring/tracking devices can include one or more types of sensors that detect, monitor, estimate, or measure particular physical parameters associated with the physical media in which they are deployed.

The (explosive) initiation device, wireless blasting-related device, wireless (explosive) initiation device, MI signal survey device, and wireless blast monitoring/tracking device, in embodiments, include each a housing, shell, case, frame and/or support structure that mechanically houses, carries, protects and/or supports at least pressure and water-sensitive elements of the device, including device-based electronic elements in the device.

Herein, reference to one or more embodiments, e.g., as various embodiments, many embodiments, several embodiments, multiple embodiments, some embodiments, certain embodiments, particular embodiments, specific embodiments, or a number of embodiments, need not or does not mean or imply all embodiments.

As used herein, the term “set” corresponds to or is defined as a non-empty finite organization of elements that mathematically exhibits a cardinality of at least 1 (i.e., a set as defined herein can correspond to a unit, singlet, or single element set, or a multiple element set), in accordance with known mathematical definitions (for instance, in a manner corresponding to that described in An Introduction to Mathematical Reasoning: Numbers, Sets, and Functions, “Chapter 11: Properties of Finite Sets” (e.g., as indicated on p. 140), by Peter J. Eccles, Cambridge University Press (1998)). Thus, a set includes at least one element. In general, an element of a set can include or be one or more portions of a system, an apparatus, a device, a structure, an object, a process, a procedure, physical parameter, or a value depending upon the type of set under consideration.

The FIGs. included herewith show aspects of non-limiting representative embodiments in accordance with the present disclosure, and particular structural elements shown in the FIGs. may not be shown to scale or precisely to scale relative to each other. The depiction of a given element or consideration or use of a particular element number in a particular FIG. or a reference thereto in corresponding descriptive material can encompass the same, an equivalent, an analogous, categorically analogous, or similar element or element number identified in another FIG. or descriptive material associated therewith. The presence of “/” in a FIG. or text herein is understood to mean “and/or” unless otherwise indicated. The recitation of a particular numerical value or value range herein is understood to include or be a recitation of an approximate numerical value or value range, for instance, within +/−20%, +/−15%, +/−10%, +/−5%, +/−2.5%, +/−2%, +/−1%, +/−0.5%, or +/−0%. The term “essentially all” or “substantially” can indicate a percentage greater than or equal to 50%, 60%, 70%, 80%, or 90%, for instance, 92.5%, 95%, 97.5%, 99%, or 100%.

Many modifications will be apparent to those skilled in the art without departing from the scope of the present invention.

Throughout this specification and the claims which follow, unless the context requires otherwise, the word “comprise”, and variations such as “comprises” and “comprising”, will be understood to imply the inclusion of a stated integer or step or group of integers or steps but not the exclusion of any other integer or step or group of integers or steps.

The reference in this specification to any prior publication (or information derived from it), or to any matter which is known, is not, and should not be taken as an acknowledgment or admission or any form of suggestion that the prior publication (or information derived from it) or known matter forms part of the common general knowledge in the field of endeavour to which this specification relates.

1. A system, the system including a range extension system for extending a range of magnetic induction (MI) signals along a pathway for commercial/civil blasting operations that use a wireless blasting-related device, the range extension system including an elongated element configured to extend the range of the MI signals along the pathway.

2. The system of claim 1, wherein the elongated element has a longitudinal length that is significantly greater than its average cross-sectional diameter.

3. The system of claim 1, including a plurality of the elongated elements configured to extend to mutually different lengths along the pathway.

4. The system of claim 1, including the wireless blasting-related device, a wireless MI signal survey device, or a wireless blast monitoring-and-tracking marker.

5. The system of claim 1, wherein the elongated element includes at least one electrical conductor configured to carry electrical signals that represent the MI signals along the elongated element in or on the electrical conductor.

6. The system of claim 5, wherein the electrical conductor includes an electrical cable configured to extend from the first element to the second element, and configured to conduct the electrical signals.

7. The system of claim 5, wherein the electrical signals include modulation frequencies that are in the MI signals.

8. The system of claim 7, including a frequency-tuning circuit to control/tune a resonant frequency of the extension system to match the modulation frequencies of the MI signals.

9. The system of claim 8, wherein the frequency-tuning circuit includes:
a first-end tuning element connected in series or in parallel with a first-end antenna; and/or
a second-end tuning element connected in series or in parallel with a second-end antenna.

10. The system of claim 8, wherein the frequency-tuning circuit includes an electronic tuning circuit with at least one capacitive element to tune the resonant frequency during use.

11. The system of claim 5, wherein the extension system includes:
a first element configured to be coupled to a first end of the elongated element, wherein the first element is configured to be placed towards a first end of the pathway, wherein the first element is configured to receive the MI signals at a start of the pathway; and/or a second element configured to be coupled to a second end of the elongated element, wherein the second end is opposite the first end, wherein the second element is configured to be placed at a second end of the pathway, wherein the second element is configured to receive the electrical signals from the elongated element, convert the electrical signals to generated MI signals, and transmit the generated MI signals to the wireless blasting-related device.

12. The system of claim 11, wherein the first element includes at least one first-end antenna configured to transduce the MI signals in intervening media from an MI transmitter into the electrical signals in the electrical conductor, and wherein the second element includes at least one second-end antenna configured to transduce the electrical signals from the electrical conductor into the generated MI signals for the wireless blasting-related device.

13. The system of claim 12, wherein the first-end antenna is formed of a first-end portion of the cable arranged around an MI antenna of the MI transmitter; and/or wherein the second-end antenna is formed of a second-end portion of the cable arranged in a coil with a plurality of turns.

14. The system of claim 11, wherein the second element is configured to fasten mechanically to the wireless blasting-related device by way of an adaptor configured to hold the second element aligned to an MI Receiver/receiver magnetometer of the wireless blasting-related device and/or to keep the second element close to the MI Receiver/receiver magnetometer of the wireless blasting-related device.

15. The system of claim 11, wherein the first element includes a first-end projection with high magnetic permeability configured to confine and guide the MI signals to the first-end antenna from the air, wherein the first-end projection includes a rigid rod or a flexible rod or flexible rope.

16. The system of claim 11, wherein the extension system includes mutual spacing between adjacent ones of a plurality of the first elements, wherein the mutual spacing is substantially the size of the first elements to mitigate interference between the adjacent ones of the first elements.

17. The system of claim 11, including a plurality of the first element and/or a plurality of the second element coupled to the elongated element.

18. The system of claim 1, wherein the elongated element guides the MI signals into and along the pathway, and wherein the MI signals travel in and along the elongated element as magnetic signals by modulation of a magnetic field in the elongated element.

19. The system of claim 1, wherein the elongated element has high electrical conductivity, forming a high conductivity guide including a conductive medium configured to receive a modulated induced current representing the MI signals induced at its first end.

20. The system of claim 1, wherein the range extension system forms a distribution network of the input MI signals by the elongated element including a plurality of elongated branches with respective second ends connected to the first end to emit/transmit generated MI signals from the second ends.
